(19) United States
(12) Patent Application Publication
(10) Pub. No.: US 2016/0277845 A1
(43) Pub. Date: Sep. 22, 2016

(54) MEMS-BASED SPEAKER IMPLEMENTATION

(71) Applicant: DSP Group LTD., Herzeliya (IL)

(72) Inventors: Haim Kupershmidt, Or Yehuda (IL); Moti Margalit, Zichron Yaaqov (IL); Adi Baram, Yokneam Ilit (IL)

(21) Appl. No.: 15/071,230

(22) Filed: Mar. 16, 2016

Related U.S. Application Data
(60) Provisional application No. 62/134,169, filed on Mar. 17, 2015.

(51) Int. Cl. H04R 19/02; H04R 19/00; H04R 31/00; B81C 1/00; B81B 3/00

(52) U.S. Cl. CPC H04R 19/02; B81C 1/00492; B81B 3/0021; H04R 31/00; H04R 19/005; B81C 2201/0109; B81C 2201/013; B81B 2201/0257; B81B 2203/0127; H04R 2201/003

(57) ABSTRACT

A micro-electromechanical system (MEMS) device that comprises a substrate, support structures, functional elements and conductive paths that comprise conductive elements; wherein the functional elements are included in a plurality of functional layers, the plurality of functional layers are spaced apart from each other; wherein the support structures are configured to provide structural support to the plurality of functional layers; wherein each functional layer is coupled to a conducting interface via a conductive path that is associated with the functional layer; and wherein the support structures comprise lateral etch stop elements.

### RELATED APPLICATIONS

This application claims priority from U.S. Provisional Patent Application Ser. No. 62/134,169 filing date Mar. 17, 2015 which is being incorporated herein by reference.

### BACKGROUND

MEMS speakers may be used in various devices.

There is a growing need to provide efficient manufacturing processes of MEMS speakers.

### SUMMARY

According to an embodiment of the invention there may be provided a MEMS device that may include a substrate, support structures, functional elements and conductive paths that include conductive elements; wherein the functional elements are included in a plurality of functional layers, the plurality of functional layers are spaced apart from each other; wherein the support structures are configured to provide structural support to the plurality of functional layers; wherein each functional layer is coupled to a conducting interface via a conductive path that is associated with the functional layer; and wherein the support structures may include lateral etch stop elements.

The etch stop elements may be electrically insulating.

Each support structure may include lateral etch stop elements that may be electrically conductive. A lateral etch stop element may be electrically insulated from a functional layer positioned below the lateral etch stop by a passivation layer pattern.

The lateral etch stop elements of the support structures may be positioned between the plurality of functional layers without electrically coupling the plurality of functional layers.

Each support structure may include a sidewall that may include one or more lateral etch stop elements that may be electrically insulating.

The sidewall of each support structure further may include one or more conductive elements that belong to a functional layer.

A given support structure may include first portions that may be included within the plurality of functional layers and second portions which may be positioned between the plurality of functional layers.

Each conductive path may be formed, at least in part, within a support structure.

The conductive paths associated with different functional layers may be formed within different support structures.

Each conductive path may include horizontal conductive elements that belong to the functions layers and vertical conductive elements positioned between the functional layers.

The support structures may include core segments that may be delimited by the lateral etch stop elements.

The one or more core segments may be made of a material selected out of Tetraethyl orthosilicate, Silicon Oxide, and undoped Silica glass (USG).

The number of functional layers of the plurality of functional layers may exceed three.

The MEMS device may include a MEMS cell that includes a membrane, a blind and a shutter.

The membrane, the blind and the shutter may belong to different functional layers of the plurality of functional layers.

The membrane, the blind and the shutter may be positioned within a space that has closed sides.

A first functional element may belong to a first functional layer and a second functional element may belong to a second functional layer.

A certain functional layer may include multiple functional elements.

All of the multiple functional elements in the same functional layer may be substantially identical to each other.

At least some functional elements of the multiple functional elements in the same functional layer may differ from each other.

All of the multiple functional elements in the same functional layer may be electrically coupled to each other.

Some of the multiple functional elements in the same functional layer may not be electrically coupled to each other.

Each functional layer of at least two functional layers may include multiple functional elements.

According to an embodiment of the invention there may be provided a method for manufacturing a micro-electromechanical system (MEMS) device, the method may include generating multiple sacrificial layer patterns and multiple conductive layer patterns by repeating the steps of depositing a sacrificial layer; patterning the sacrificial layer to provide a sacrificial layer pattern; depositing a passivation layer; removing an upper part of the passivation layer to expose the sacrificial layer pattern; depositing a conductive layer; and patterning the conductive layer, thereby forming a conductive layer pattern. Following repetition of these steps (N−1) times (N being the number of functional layers in the device), depositing the top (N-th) sacrificial layer; patterning the top sacrificial layer to provide a top sacrificial layer pattern; depositing a top passivation layer; removing the upper part of the top passivation layer to expose the sacrificial layer pattern; depositing a top conductive layer; depositing a metal layer; patterning the metal layer to provide a metal layer pattern; patterning the top conductive layer thereby forming a conductive layer pattern; and removing, by applying an etch process, each sacrificial layer pattern that is exposed to the etch process thereby exposing support structures and functional elements that are formed by the multiple conductive layer patterns and the top conductive layer pattern; wherein the functional elements are included in a plurality of functional layers, the plurality of functional layers are spaced apart from each other; wherein the support structures are configured to provide structural support to the plurality of functional layers; and wherein the support structures comprise electrically insulating lateral etch stop elements.

The multiple conductive layer patterns may define edges of the insulating support structures and/or the functional elements.

According to an embodiment of the invention there may be provided a method for manufacturing a micro-electromechanical system (MEMS) device, the method may include depositing a passivation layer on a substrate and patterning the passivation layer to provide a passivation layer pattern; generating multiple sacrificial layer patterns and multiple conductive layer patterns by repeating the steps of: depositing a sacrificial layer; patterning the sacrificial layer to provide a sacrificial layer pattern; depositing a conductive layer; depositing a passivation layer; patterning the passivation layer to provide a passivation layer pattern; and patterning the conductive layer thereby forming a conductive layer pattern. Following repetition of these steps (N−1) times (N being the number of functional layers in the device), depositing the top (N-th) sacrificial layer; patterning the top sacrificial layer to provide a sacrificial layer pattern; depositing a top conductive layer; depositing a metal layer; patterning the metal layer to provide a metal layer pattern; and patterning the top conductive layer thereby forming a top conductive layer pattern and removing, by applying an etch process, each sacrificial layer pattern that is exposed to the etch process thereby exposing support structures and functional elements that are formed by the multiple conductive layer patterns and the top conductive layer pattern; wherein the functional elements are included in a plurality of functional layers, the plurality of functional layers are spaced apart from each other; wherein the support structures are configured to provide structural support to the plurality of functional layers; and wherein the support structures comprise electrically conductive lateral etch stop elements.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a cross sectional view of a prior art speaker;

FIG. 2 is a top view of an illustrative embodiment of a prior art speaker array;

FIG. 3 illustrates an array of set of supporting elements according to an embodiment of the invention;

FIG. 4 illustrates a set of supporting elements according to an embodiment of the invention;

FIG. 5 illustrates an array of set of supporting elements according to an embodiment of the invention;

FIG. 6 illustrates a first layer that includes a membrane and a set of supporting elements according to an embodiment of the invention;

FIG. 7 illustrates a second layer that includes a blind and a set of supporting elements according to an embodiment of the invention;

FIG. 8 illustrates a third layer that includes a shutter and a set of supporting elements according to an embodiment of the invention;

FIG. 9 illustrates a second layer and a mask of a second intermediate layer that is positioned between the second and third layers according to an embodiment of the invention;

FIG. 10 illustrates a mask of a second intermediate layer positioned between the second and third layers according to an embodiment of the invention;

FIG. 11 illustrates a mask of the third layer that also include bond pads and connections to the bond pads according to an embodiment of the invention;

FIG. 12 illustrates a mask of the second layer that also includes supporting elements positioned below the bond pads and connections to the bond pads of the third layer according to an embodiment of the invention;

FIG. 13 is a cross sectional view of a speaker according to an embodiment of the invention;

FIG. 14 illustrates a method according to an embodiment of the invention;

FIG. 15 illustrates a method according to an embodiment of the invention;

FIGS. 16-37 include top views and cross sectional views of a MEMS device during different manufacturing steps according to an embodiment of the invention;

FIGS. 38-45 illustrate various masks according to various embodiments of the invention; and

FIGS. 46-67 include top views and cross sectional views of a MEMS device during different manufacturing steps according to an embodiment of the invention.

### DETAILED DESCRIPTION OF THE DRAWING

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

This application describes a MEMS implementation of Picospeaker based on principle of operation as disclosed in U.S. Pat. No. 8,861,752.

The speaker is based on an array of MEMS cells a substantially identical shape, with three layers: the Ultra-Sound Membrane layer, the perforated plate layer and the shutter layer. The membranes of the membrane layer in each cell oscillate at ultrasonic frequencies and get modulated by the audio signal intended to be rendered by the speaker. The perforated plate layer and/or the shutter layer may oscillate or be static.

The perforated layer and the shutter act together as an ultrasonic modulator, thus effectively doing frequency-shift to the modulated ultrasonic signal coming from the membrane, thus causing the audio to be rendered.

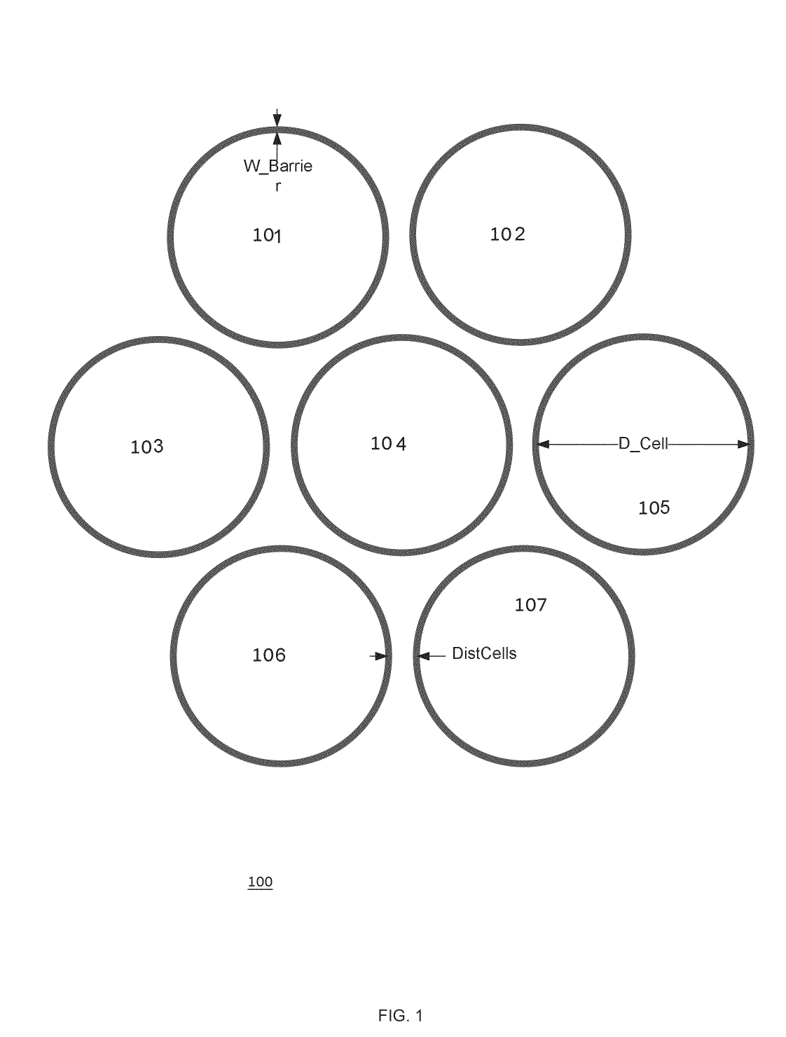

FIG. 1 shows the mask 100 for the etching release barriers of the individual cells, at the layer below the lower membrane. Each cell here is depicted in round shape, but it should be noted that this may not be so, and the actual shape may be hexagon, square, or of some other form.

FIG. 1 shows an array of seven such cells (101, 102, 103, 104, 105, 106 and 107 in the figure). This mask 100 is used for etching release barriers for individual cells. The cells diameter is D_Cell, the distance between cells is DistCells, and the etching release barriers are of width W Barrier. The shaded areas (the perimeter of each cell) is etched and may be filled by PolySi or another material.

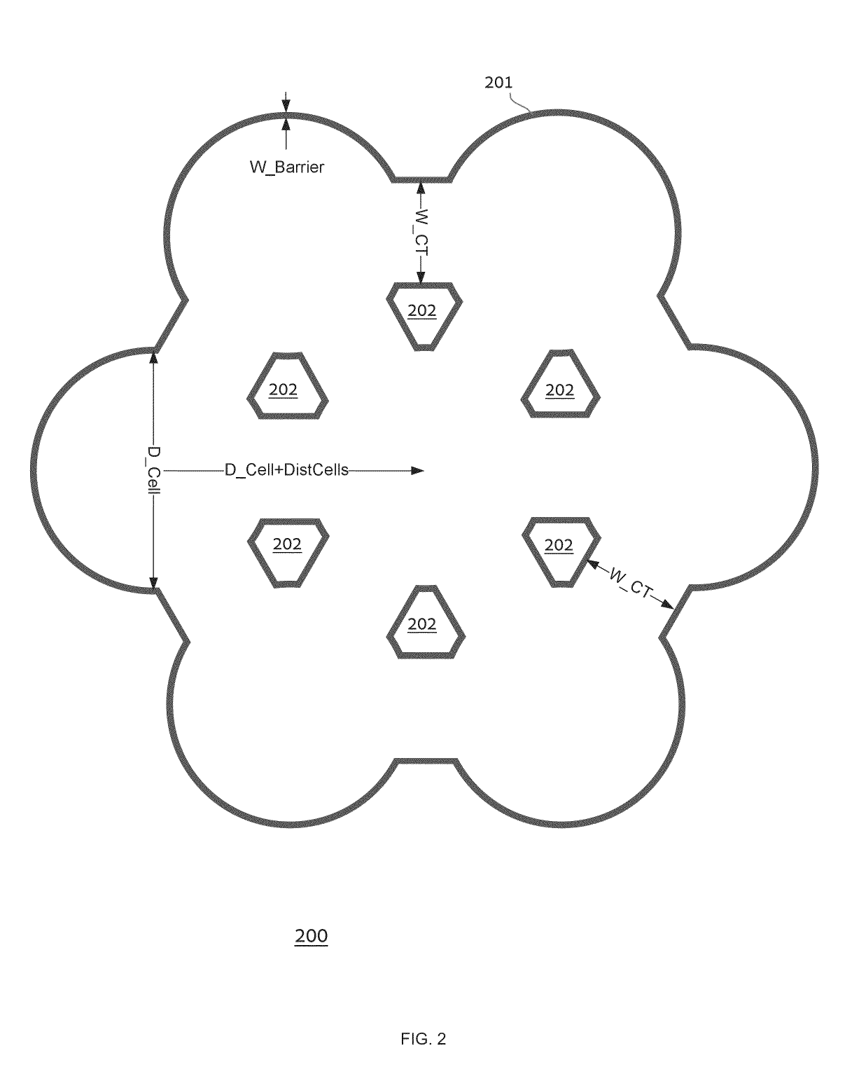

FIG. 2 shows mask 200 for an alternative implementation of the release barriers. In this example, the individual cells below the membrane are not isolated acoustically, but are interconnected by channels of width W_CT. For some implementations, such acoustic coupling may prove beneficial for device operation and efficiency. Mask 200 includes a perimeter 201 that surrounds the vertical trajectories of cells 101-107 of FIG. 1 on the plane of mask 200. Mask also includes inner spaces 202 that correspond to spaces between the locations of cells 101-107 of mask 100.

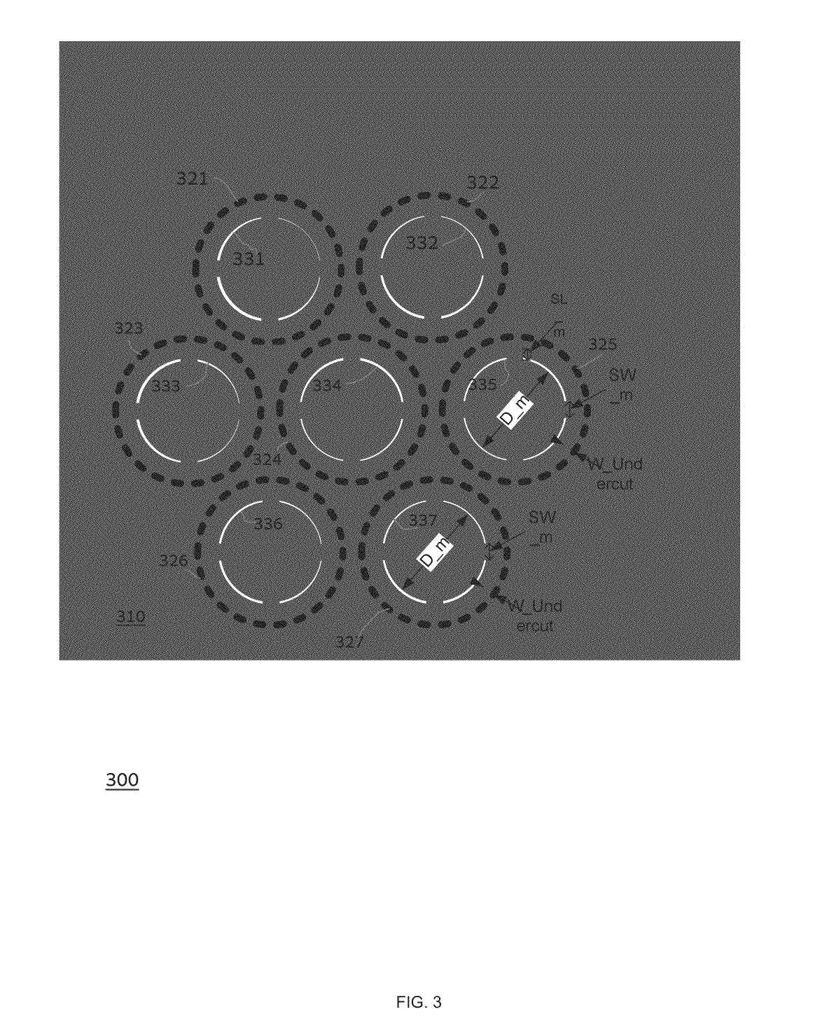

FIG. 3 shows the mask 300 for the membrane layer of the array. The shaded area 310 is not etched. This layer is implemented by a conductive material (e.g. doped PolySi), and thus all membranes of this array are connected between each other. The diameter of the membrane is D_m and the springs dimensions are given by SW_m and SL_m.

The mask 300 includes seven groups 331, 332, 333, 334, 335, 336 and 337 of apertures-each group includes four arc shaped apertures. The groups of apertures are surrounded by etch barriers (dotted circles) 321, 322, 323, 324, 325, 326 and 327.

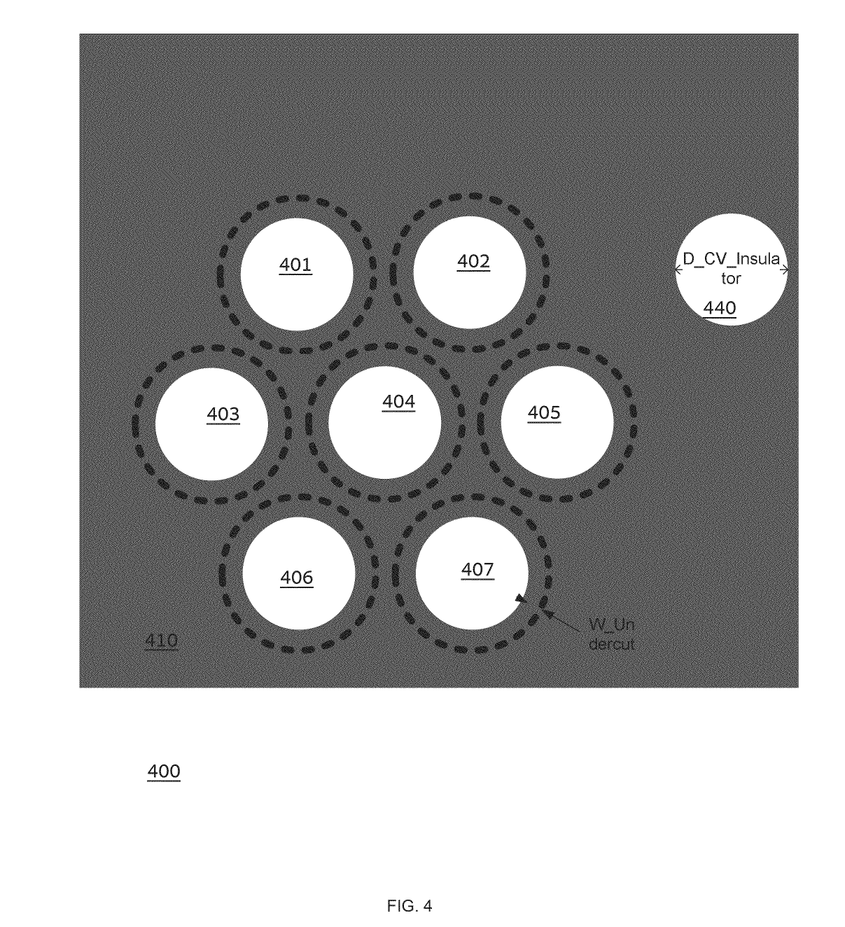

FIG. 4 shows an insulation layer 400 grown immediately above the membrane layer, with a membrane layer contact via used to actuate the membrane. It includes apertures 401, 402, 403, 404, 405, 406 and 407 and an aperture 440 for a support element—formed within shaded area 410 that is not etched.

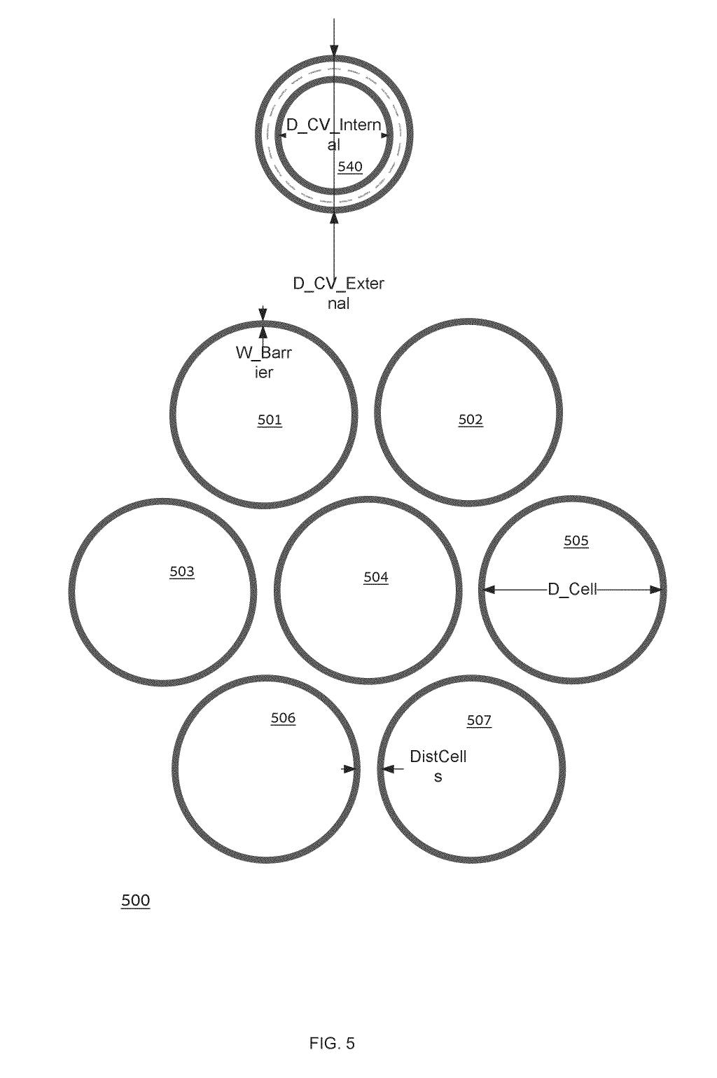

FIG. 5 is similar to FIG. 1 and illustrates a mask 500 for etching release barriers between the membrane and the perforated layer. Mask 500 includes seven apertures 501, 502, 503, 504, 505, 506 and 507—from seven cells 101-107. The membrane layer contact via 504 (an example of a supporting structure) is also shown here, with two concentric barriers for etching, of diameters D_CV_Internal and D_CV_External. The D_CV_External barrier encapsulates the via above the respective contact provided by the hole 240 in the insulation layer shown in FIG. 2 (D_CV_Insulator). D_CV_Internal, when etched and filled with doped PolySi, provides electrical contact through the via.

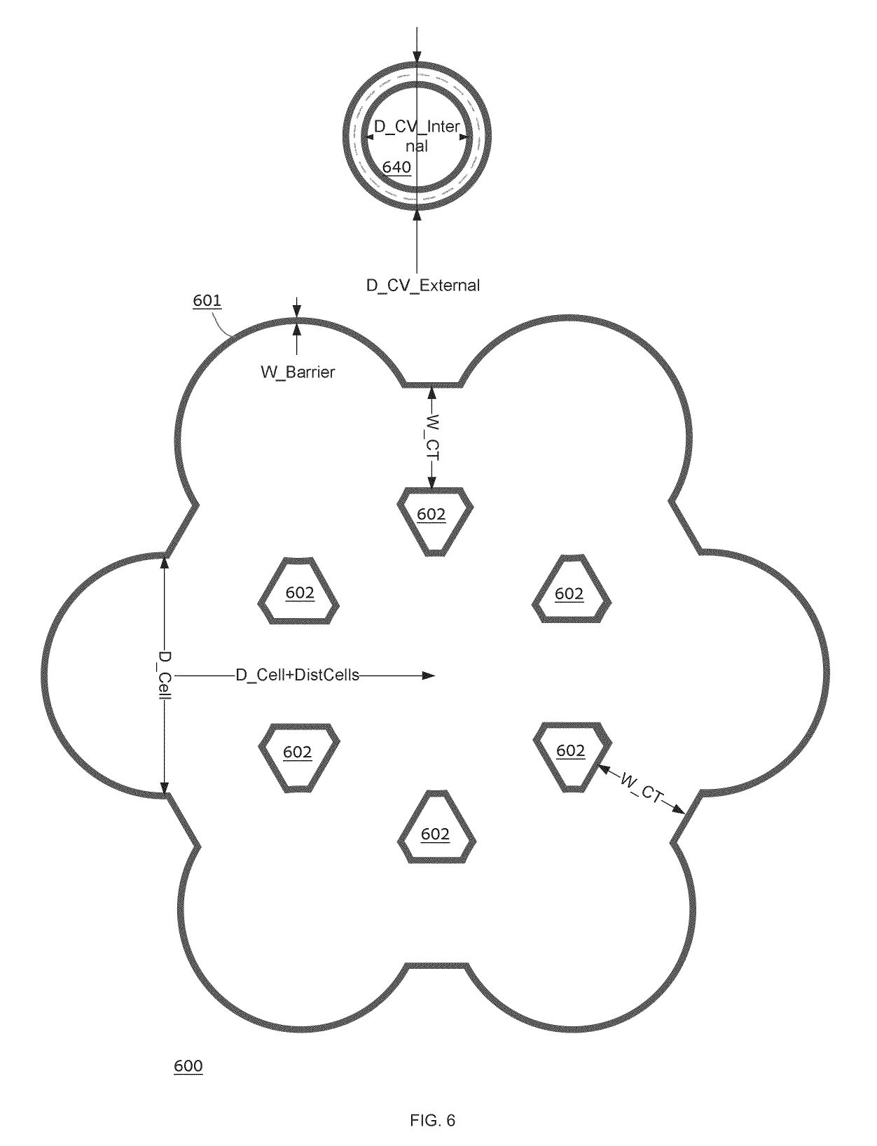

FIG. 6 shows an alternative implementation of the barriers of the cell box between the membrane and the perforated layer. Mask 600 includes a perimeter 601 that surrounds the vertical trajectories of cells 101-107 of FIG. 1 on the plane of mask 600. Mask also includes inner spaces 602 that correspond to spaces between the locations of cells 101-107 of mask 100.

The individual cells obtained when using masks 100, 200, 300, 400, 500 and 600 are acoustically coupled through tunnels of width W_CT. For some implementations, such acoustic coupling may prove beneficial for device operation and efficiency.

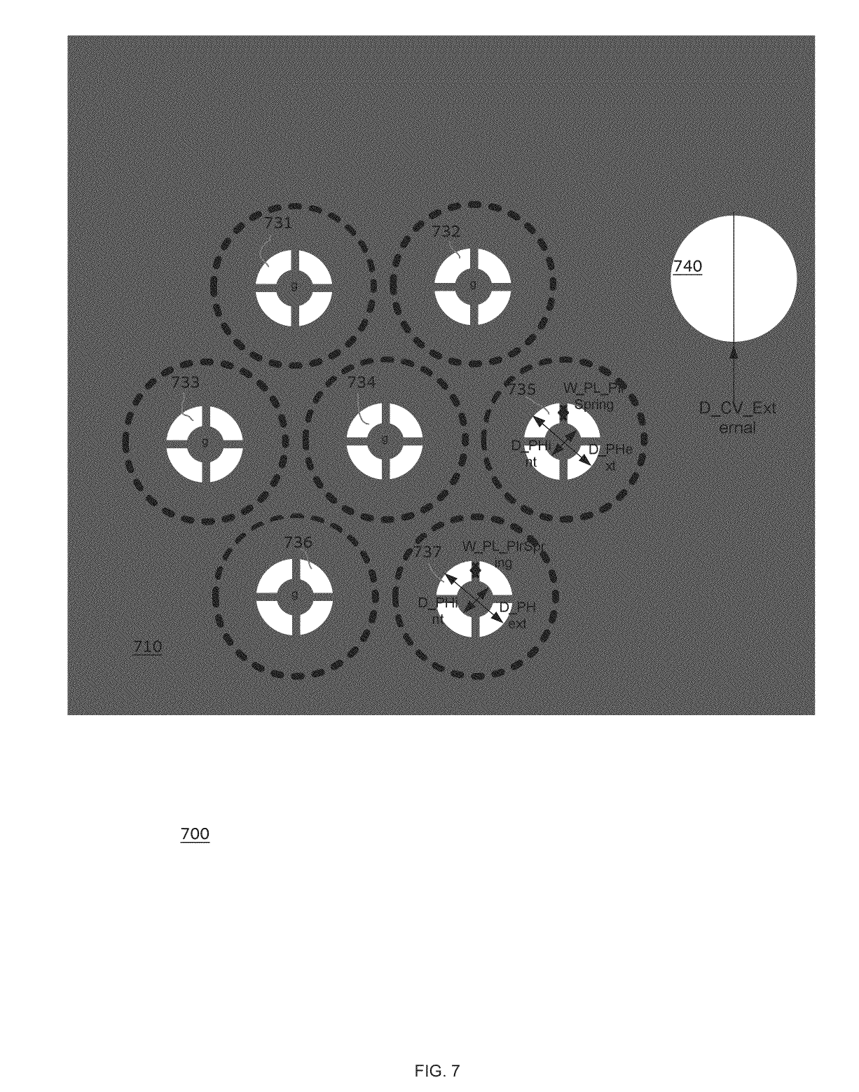

FIG. 7 shows the mask 700 of the perforated layer (blind layer). Mask 700 includes a hole 740 for the membrane layer contact via. The perforated layer in this example includes seven groups 731, 732, 733, 734, 735, 736 and 737 of apertures—each group includes four spaced apart arc shaped apertures that form a ring-shaped area with an internal diameter D_PHint, external parameter D_PHext and springs of width W_PL_PlrSpring.

Hole 740 and seven groups 731, 732, 733, 734, 735, 736 and 737 of apertures are formed within a shaded area 710 that is not etched.

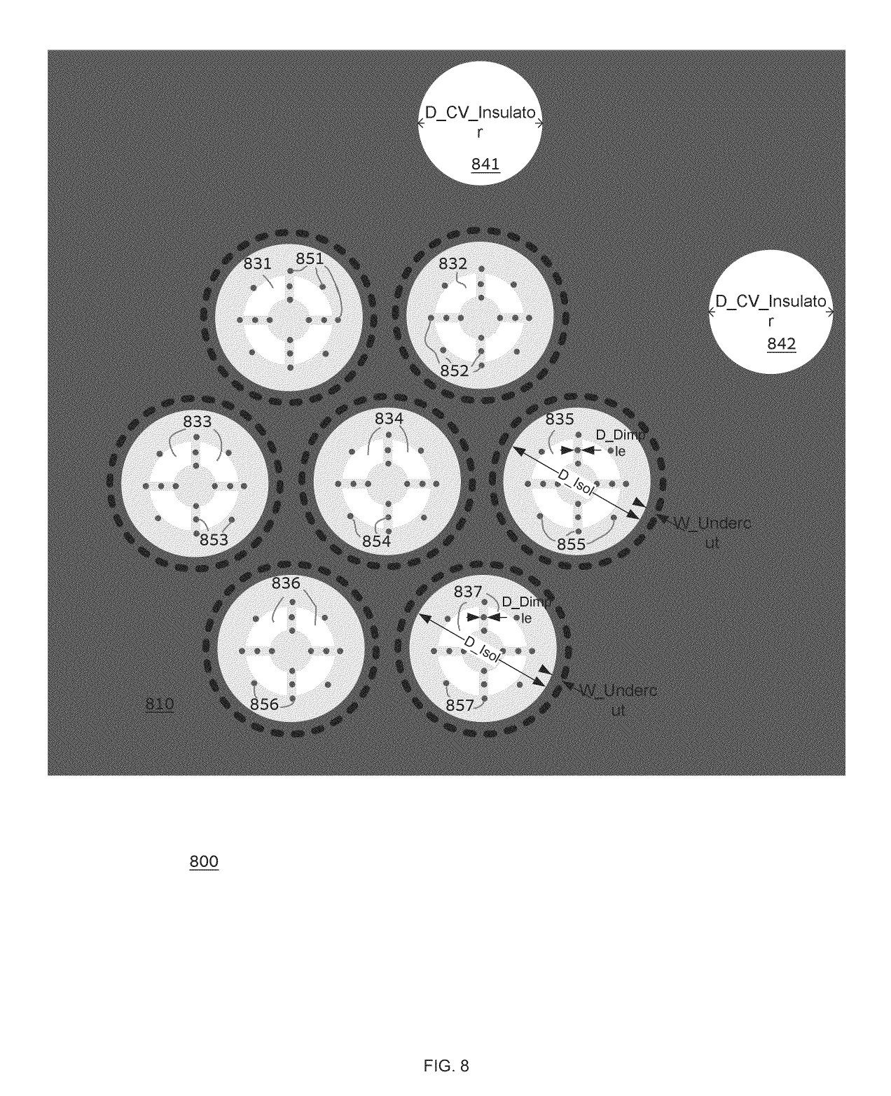

FIG. 8 provides the mask 800 for the insulation layer of the perforated layer. It also shows two holes 841 and 842 for contact vias: one for the membrane layer contact via, and one for the perforated layer contact via.

Mask 800 includes a shaded area 810 that is not etched, holes 841 and 841 and seven groups 831, 832, 833, 834, 835, 836 and 837 of apertures—each group includes seven spaced apart arc shaped apertures—all formed within shaded area 810 that is not etched.

FIG. 8 also shows “dimples” 851, 852, 853, 854, 855, 856 and 857 of contact interface structures which are designed to prevent stiction between the perforated layer and the shutter layer.

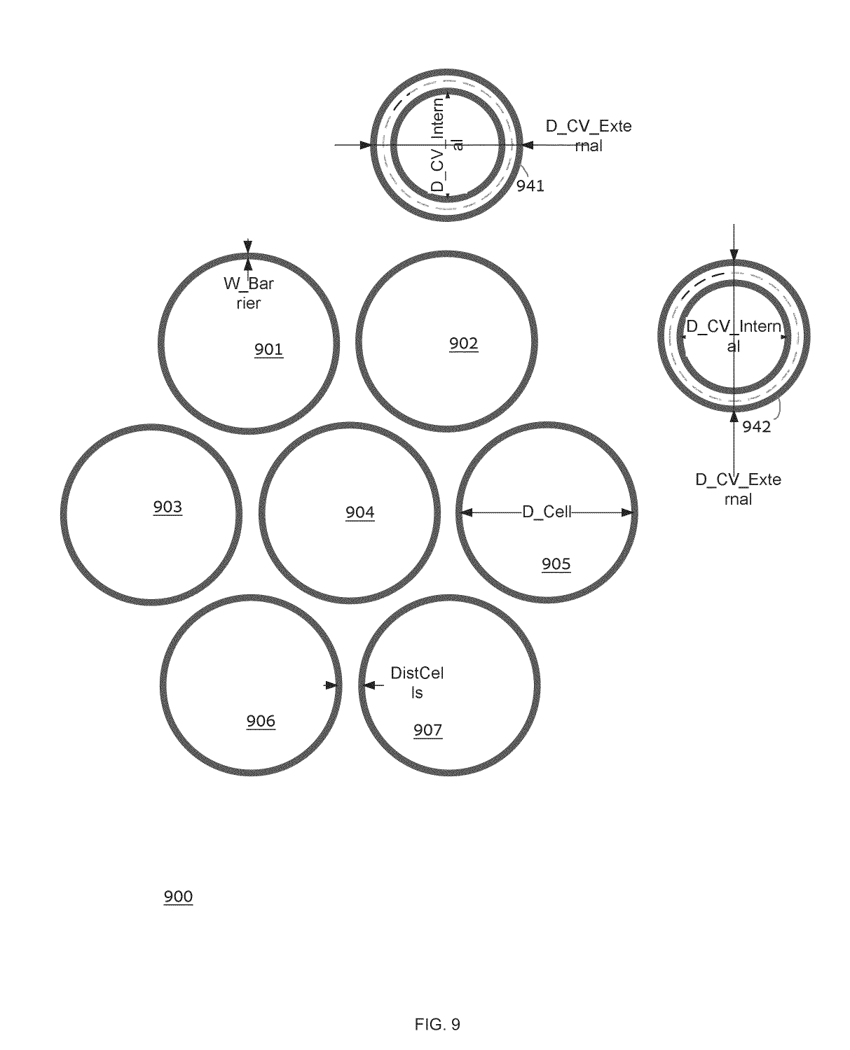

FIG. 9 shows a mask 900 which is similar to mask 200 of FIG. 2 and mask 600 of FIG. 6, and this time the mask is designed for structure of the cell between the perforated layer and the shutter. Mask 900 includes a perimeter 901 that surrounds the vertical boundaries of cells 101-107 of FIG. 1 on the plane of mask 900. Mask 900 also includes inner spaces 902 that correspond to the locations of cells 101-107 of mask 100. Mask 900 further includes two pairs of coaxial circles—941 and 942—for contact vias, for membrane contact via and the perforated layer contact via. These structures are substantially identical to the one described in FIG. 3.

Each pair of coaxial circles includes two concentric barriers for etching, of diameters D_CV_Internal and D_CV_External. The D_CV_External barrier encapsulates the via above the respective contact provided by the hole in the insulation layer. D_CV_Internal, when etched and filled with doped PolySi, provides electrical contact through the via.

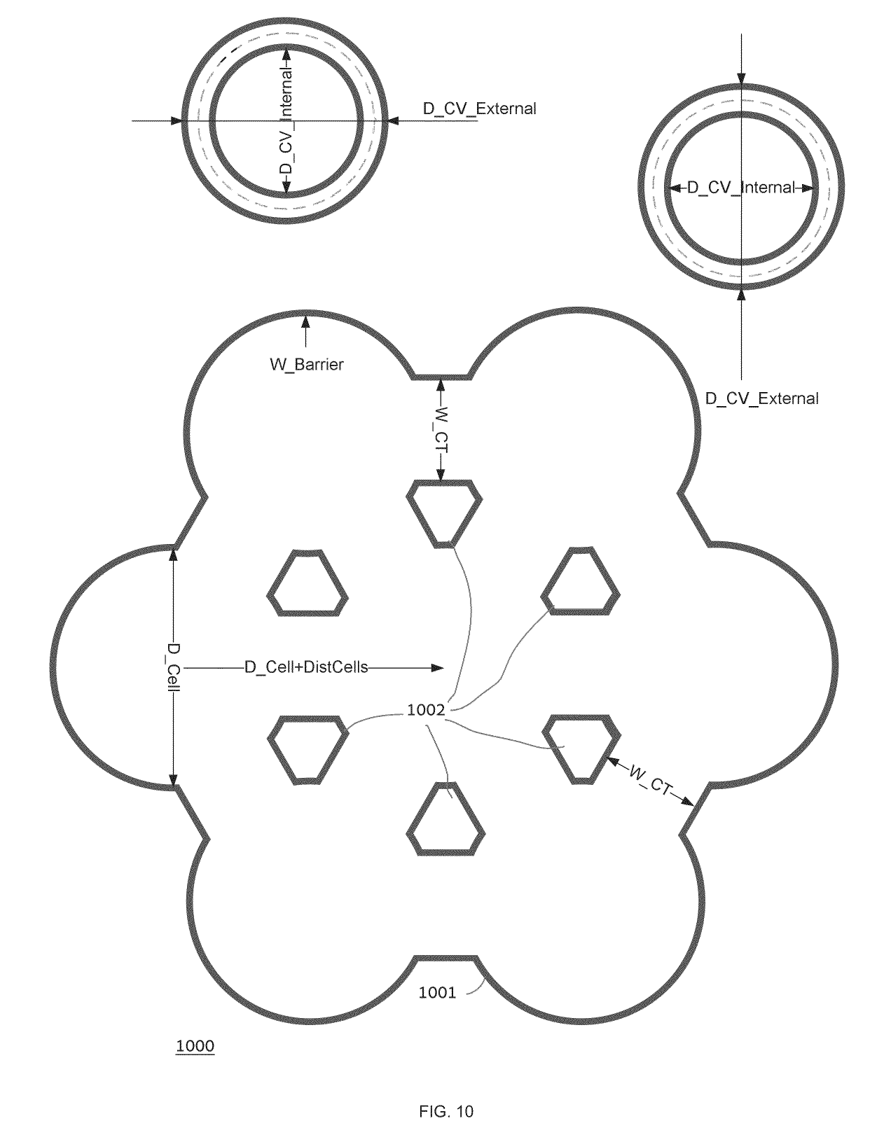

FIG. 10 is an alternative implementation of mask shown in FIG. 9. Similarly to FIG. 2 and FIG. 7, in this alternative the boxes of individual cells are acoustically coupled. In FIG. 10 the coupling between the perforated layer and the shutter is achieved, like in FIGS. 2 and 7, by an interconnection of width W_CT.

Mask 1000 includes a perimeter 1010 that surrounds the vertical boundaries of cells 101-107 of FIG. 1 on the plane of mask 1000. Mask 1000 also includes inner spaces 1002 that correspond to spaces between the locations of cells 101-107 of mask 100. Mask 1000 further includes two pairs of coaxial circles—1041 and 1042—for contact vias, for membrane contact via and the perforated layer contact via.

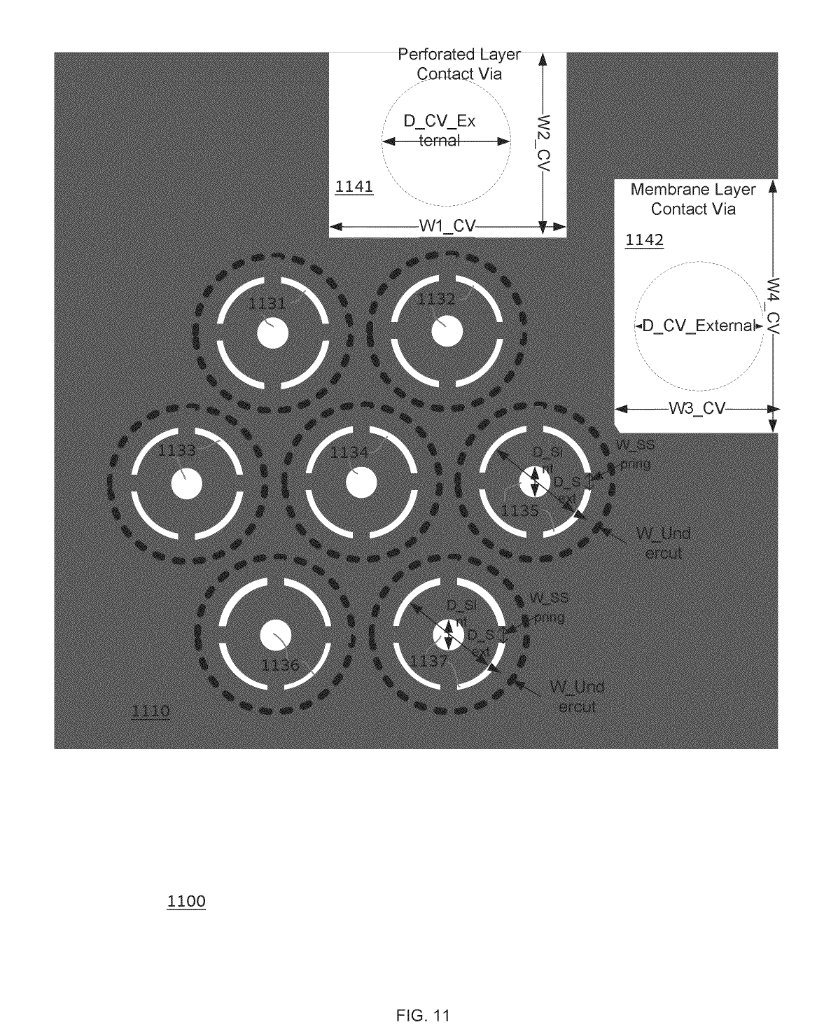

FIG. 11 shows the mask 1100 for the shutter layer. In this example each shutter of the seven shutters is shaped as a ring overlapping the perforated ring of the Perforated Layer shown in FIG. 7. The parameters determining the shape of the shutter in this example are D_Sint (diameter of the internal circle of the ring), D_Sext (diameter of the external circle of the ring) and the width of the springs W_SSpring. The shaded areas 1110 of the mask 1100 are the ones which are not etched. The same mask leaves uncovered the areas of perforated layer contact via and the membrane layer contact via.

The mask 1100 defines seven groups 1131, 1132, 1133, 1134, 1135, 1136 and 1137 of apertures, each group of apertures includes a central hole and four spaced apart arc shaped.

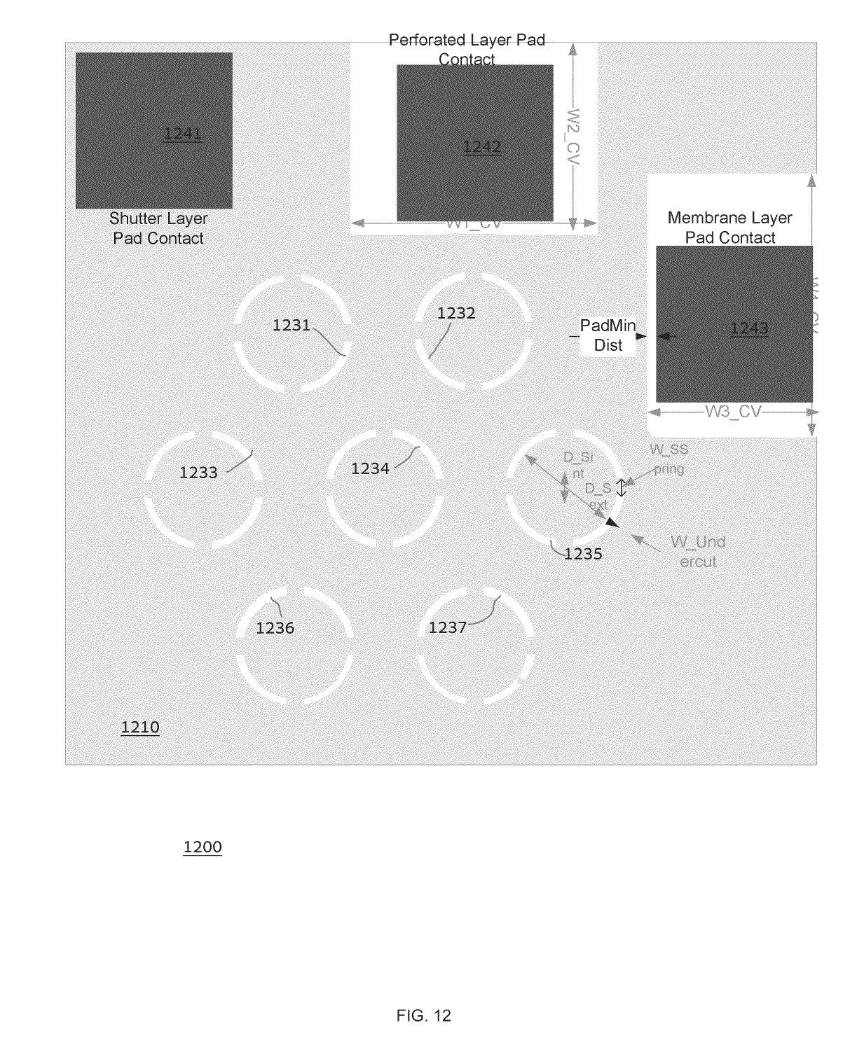

FIG. 12 shows the mask 1200 for Contact Pads. The three contact pads 1241, 1242 and 1243 are shown (membrane layer contact pad, perforated layer contact pad and the shutter layer contact pad) provide contacts for feeding and actuation of the 3 layers of the device.

FIG. 12 shows, for reference, also seven groups 1231, 1232, 1233, 1234, 1235, 1236 and 1237 of apertures, corresponding to the seven groups 1131, 1132, 1133, 1134, 1135, 1136 and 1137 shown in FIG. 1100 of shutter mask.

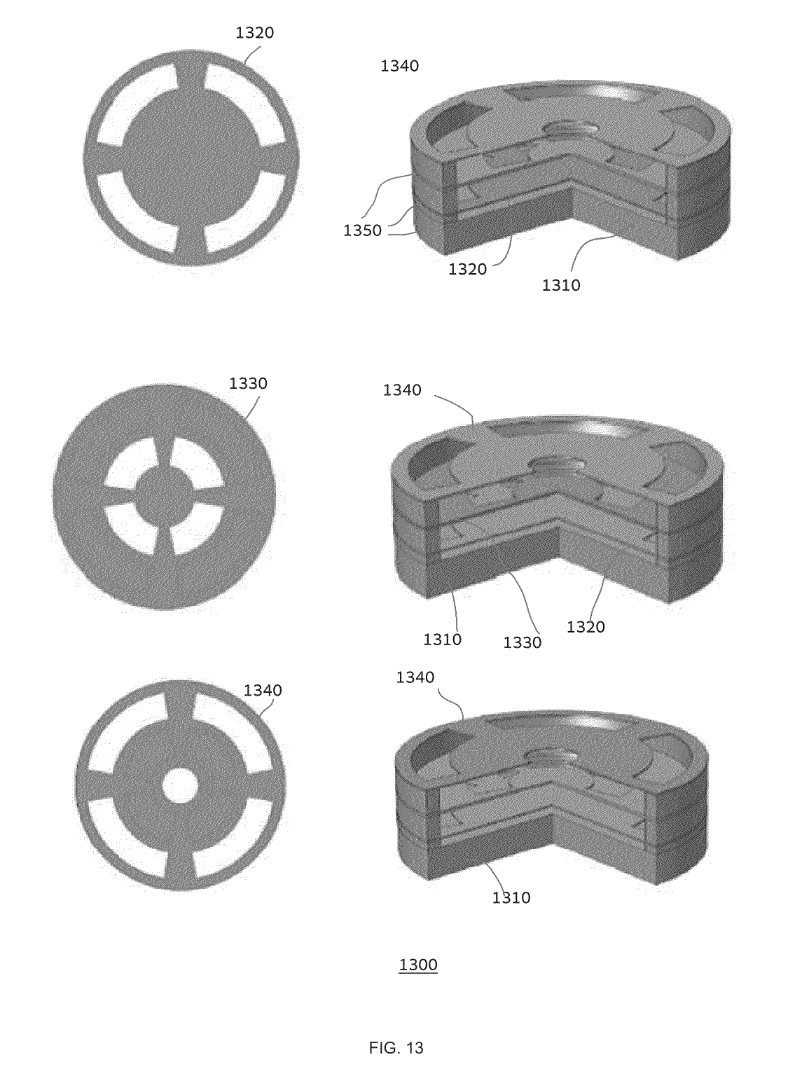

FIG. 13 shows a three dimensional cross-section of a single MEMS cell of the MEMS device according to an embodiment of the invention. FIG. 13 illustrates substrate 1310, membrane layer 1320, blind layer 1330 and shutter layer 1340. Spacers 1350 are positioned between each one of substrate 1310, membrane, 1320, blind layer 1330 and shutter layer 1340.

A MEMS device may be a MEMS speaker that may include one or more MEMS cells. When there are more than a single MEMS cell then the MEMS speaker may include an array of MEMS cells that may be fabricated by using the masks of FIGS. 1-12.

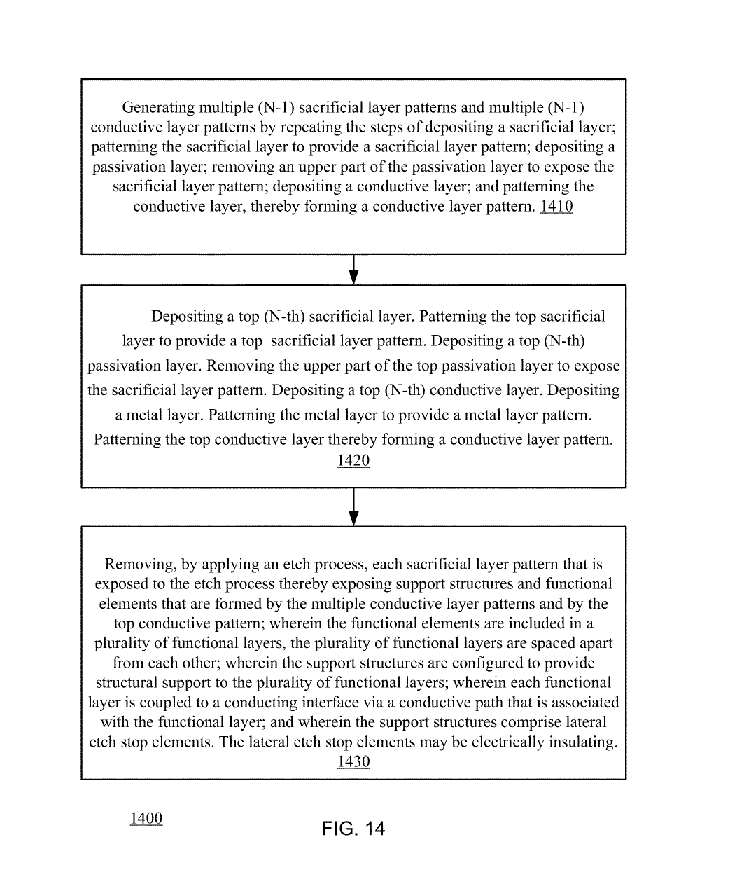

FIG. 14 illustrates a method 1400 according to an embodiment of the invention.

It is assumed that the MEMS device has N functional layers, N being a positive integer.

Method 1400 may start by step 1410 of generating multiple sacrificial layer patterns, multiple passivation layer patterns, and multiple conductive layer patterns by repeating (for example N−1 times) the steps of: depositing a sacrificial layer; patterning the sacrificial layer to provide a sacrificial layer pattern; depositing a passivation layer; removing an upper part of the passivation layer to expose the sacrificial layer pattern; depositing a conductive layer; and patterning the conductive layer, thereby forming a conductive layer pattern.

The removing of the upper part of the passivation layer exposes the top sacrificial layer and exposes the passivation layer elements that are located within the sacrificial layer. The conductive layer is then deposited on a plane.

Step 1410 may include performing multiple (N−1) manufacturing iterations. The layers of one manufacturing iterations are deposited on each other and on the layers manufactured during the previous manufacturing iterations.

The patterning of each sacrificial layer of step 1410 may include creating a photoresist layer pattern; developing the photoresist pattern; etching the sacrificial layer to form the sacrificial layer pattern; wherein the etching comprises removing completely all sacrificial layers parts not covered by the photoresist pattern.

Step 1410 may be followed by step 1420 of depositing a top sacrificial layer. Patterning the top sacrificial layer to provide a top sacrificial layer pattern. Depositing a top passivation layer. Removing the upper part of the top passivation layer to expose the sacrificial layer pattern. Depositing a top conductive layer. Depositing a metal layer. Patterning the metal layer to provide a metal layer pattern. Patterning the top conductive layer thereby forming a conductive layer pattern. The planarization exposes the top sacrificial layer and the passivation layer elements within the top sacrificial layer.

Step 1420 may be followed by step 1430 of removing, by applying an etch process, each sacrificial layer pattern that is exposed to the etch process thereby exposing support structures and functional elements that are formed by the multiple conductive layer patterns and by the top conductive pattern; wherein the functional elements are included in a plurality of functional layers, the plurality of functional layers are spaced apart from each other; wherein the support structures are configured to provide structural support to the plurality of functional layers; wherein each functional layer is coupled to a conducting interface via a conductive path that is associated with the functional layer; and wherein the support structures comprise lateral etch stop elements. The lateral etch stop elements may be electrically insulating.

The multiple conductive layer patterns may define the functional elements and/or define edges of the support structures.

Method 1400 may be used to manufacture a MEMS device that includes a substrate, support structures and functional elements; wherein the functional elements may be included in a plurality of functional layers, the plurality of functional layers may be spaced apart from each other; wherein the support structures may be conductive and may be configured to provide structural support to the plurality of functional layers;

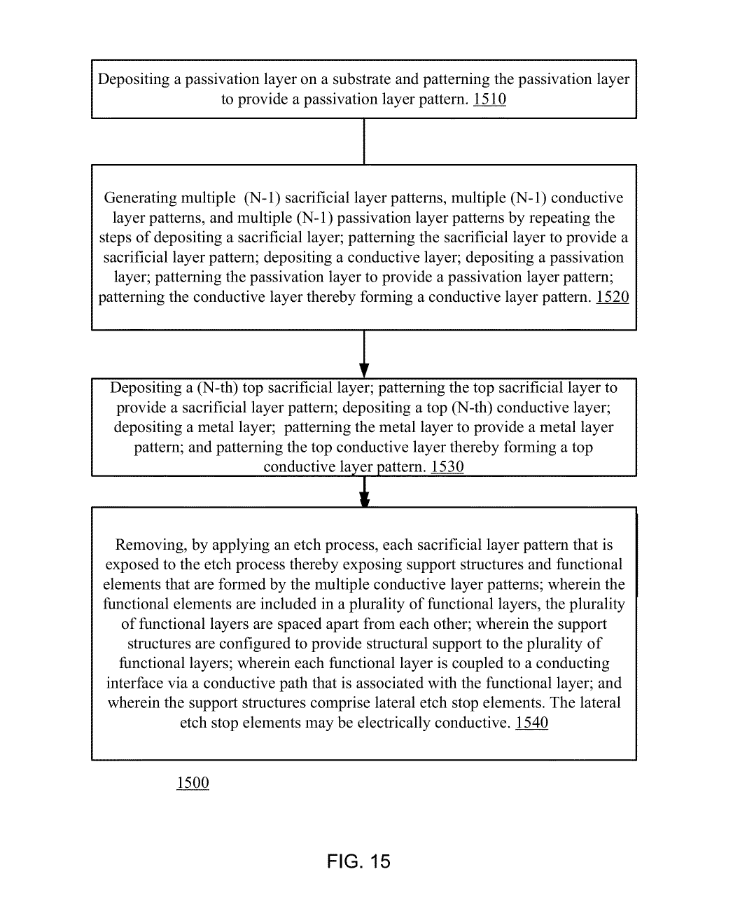

FIG. 15 illustrates a method 1500 according to an embodiment of the invention.

Method 1500 may start by step 1510 of depositing a passivation layer on a substrate and patterning the passivation layer to provide a passivation layer pattern.

Step 1510 may be followed by step 1520 of generating multiple sacrificial layer patterns, multiple passivation layer patterns, and multiple conductive layer patterns by repeating (for example N−1 times) the steps of depositing a sacrificial layer; patterning the sacrificial layer to provide a sacrificial layer pattern; depositing a conductive layer; depositing a passivation layer; patterning the passivation layer to provide a passivation layer pattern and patterning the conductive layer thereby forming a conductive layer pattern.

Step 1520 may include performing multiple manufacturing iterations. Each manufacturing iterations includes depositing a sacrificial layer, patterning the sacrificial layer to provide a sacrificial layer pattern, depositing a conductive layer and patterning the conductive layer thereby forming a conductive layer pattern.

The sacrificial layer patterned during a manufacturing iteration is deposited on top of the conductive layer pattern formed during the previous manufacturing iteration.

The patterning of each sacrificial layer of step 1520 may include creating a photoresist layer pattern; developing the photoresist pattern; etching the sacrificial layer to form the sacrificial layer pattern; wherein the etching may include removing completely all sacrificial layers parts not covered by the photoresist pattern.

Step 1520 may be followed by step 1530 of depositing a top sacrificial layer; patterning the top sacrificial layer to provide a sacrificial layer pattern; depositing a top conductive layer; depositing a metal layer; patterning the metal layer to provide a metal layer pattern; and patterning the top conductive layer thereby forming a top conductive layer pattern.

Step 1530 may be followed by step 1540 of removing, by applying an etch process, each sacrificial layer pattern that is exposed to the etch process thereby exposing support structures and functional elements that are formed by the multiple conductive layer patterns; wherein the functional elements are included in a plurality of functional layers, the plurality of functional layers are spaced apart from each other; wherein the support structures are configured to provide structural support to the plurality of functional layers; wherein each functional layer is coupled to a conducting interface via a conductive path that is associated with the functional layer; and wherein the support structures include lateral etch stop elements. The lateral etch stop elements may be electrically conductive.

FIGS. 16-37 include top views and cross sectional views of a MEMS device during different manufacturing steps according to an embodiment of the invention. FIGS. 16-37 illustrate a manufacturing process in which lateral etch stop elements positioned between the functional layers are electrically insulating. The MEMS device of FIGS. 16-37 may be manufactured by executing method 1400. It is noted that in these figures the single cell is not of circular, but of hexagon shape.

FIG. 16 illustrates substrate 11 and a sacrificial layer 12 formed on substrate.

FIG. 17 illustrates the patterning of sacrificial layer 12—for example by forming holes 12′. The patterned sacrificial layer is now denoted 12″. FIG. 17 also illustrates a top view 171.

FIG. 18 illustrates the depositing of passivation layer 13. The passivation layer 13 includes an upper part that is positioned on the top of patterned sacrificial layer 12″ and electrically insulating etch stop elements 13′ that fill holes 12′.

FIG. 19 illustrates the removal of the upper part of the passivation layer and the exposing of the electrically insulating etch stop elements 13′.

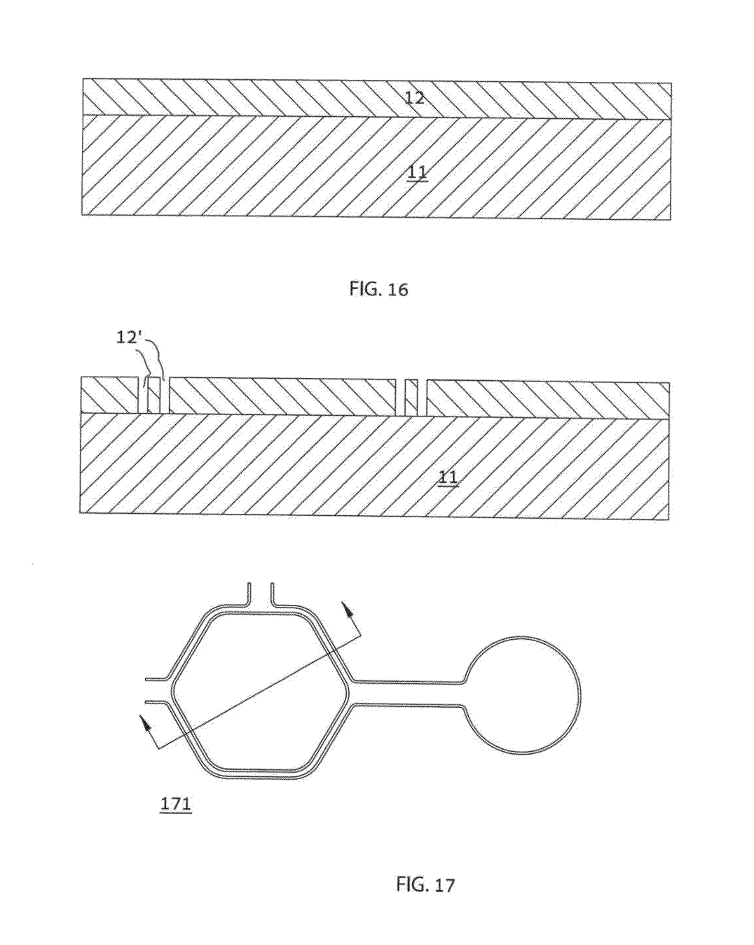

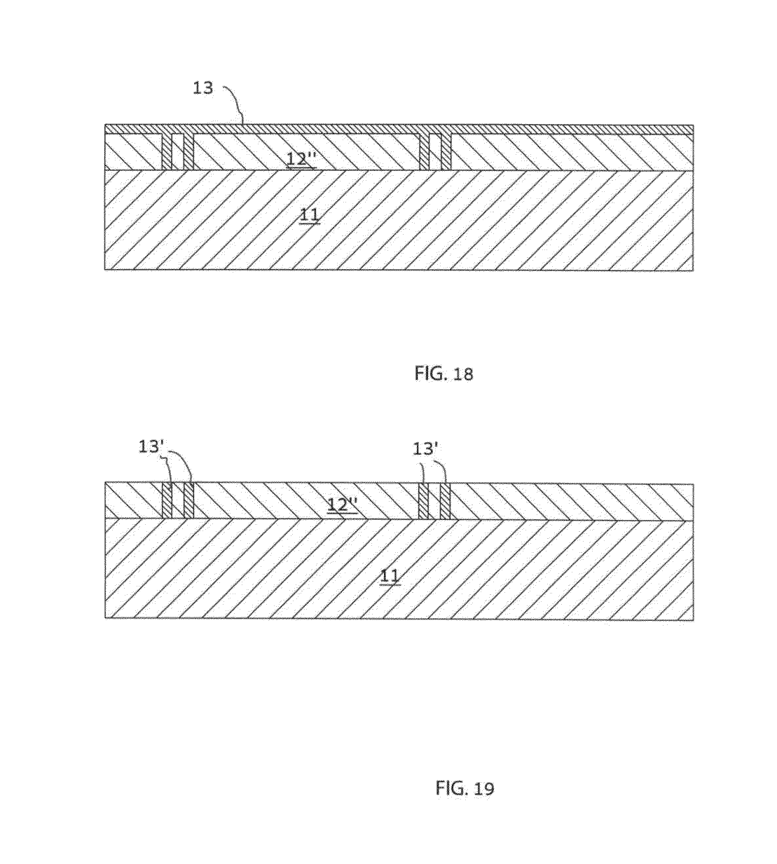

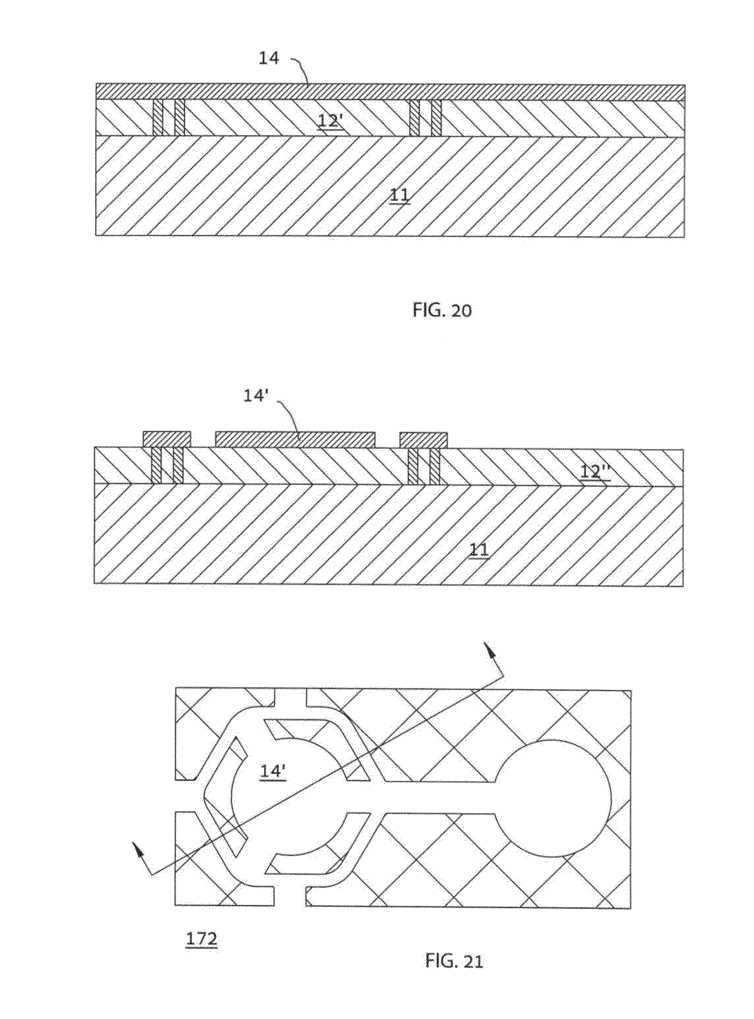

FIG. 20 illustrates the depositing of conductive layer 14.

FIG. 21 illustrates the patterning of conductive layer 14 to form conductive layer patterns 14′ such as a membrane. FIG. 21 also includes top view 172.

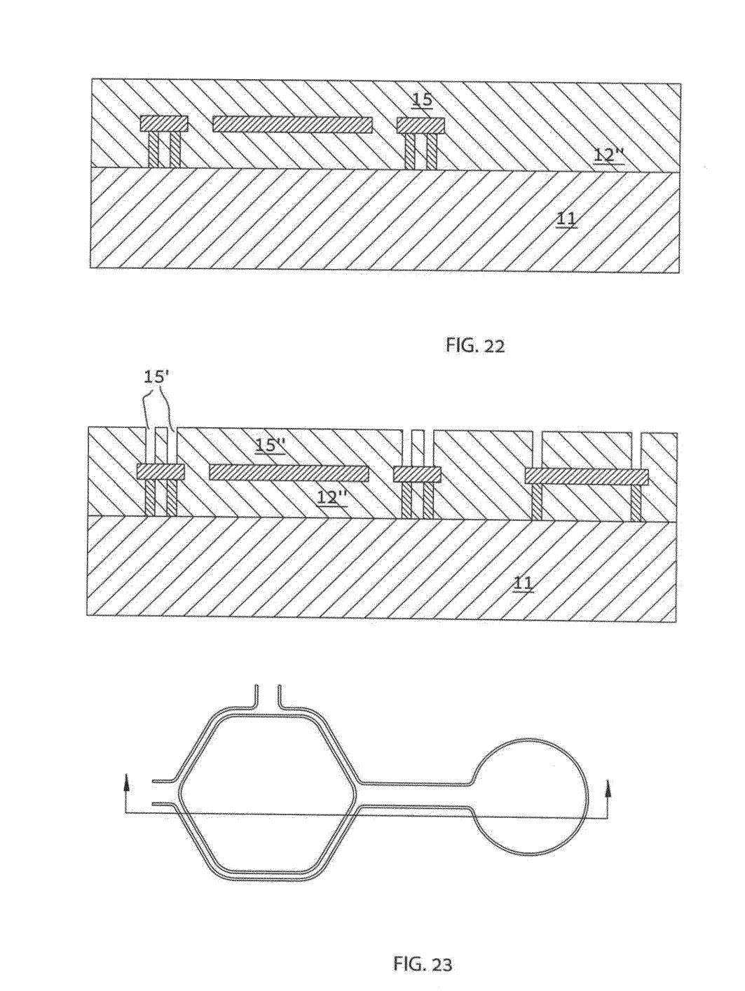

FIG. 22 illustrates the formation of sacrificial layer 15 on conductive layer patterns 14′ and on parts of patterned sacrificial layer 12″ not covered by conductive layer patterns 14′.

FIG. 23 illustrates the patterning of sacrificial layer 15—for example by forming holes 15′. The patterned sacrificial layer is now denoted 15″. FIG. 23 also illustrates a top view

FIG. 24 illustrates the depositing of passivation layer 16. The passivation layer 16 includes an upper part that is positioned on the top of patterned sacrificial layer 15″ and electrically insulating etch stop elements 16′ that fill holes 15′.

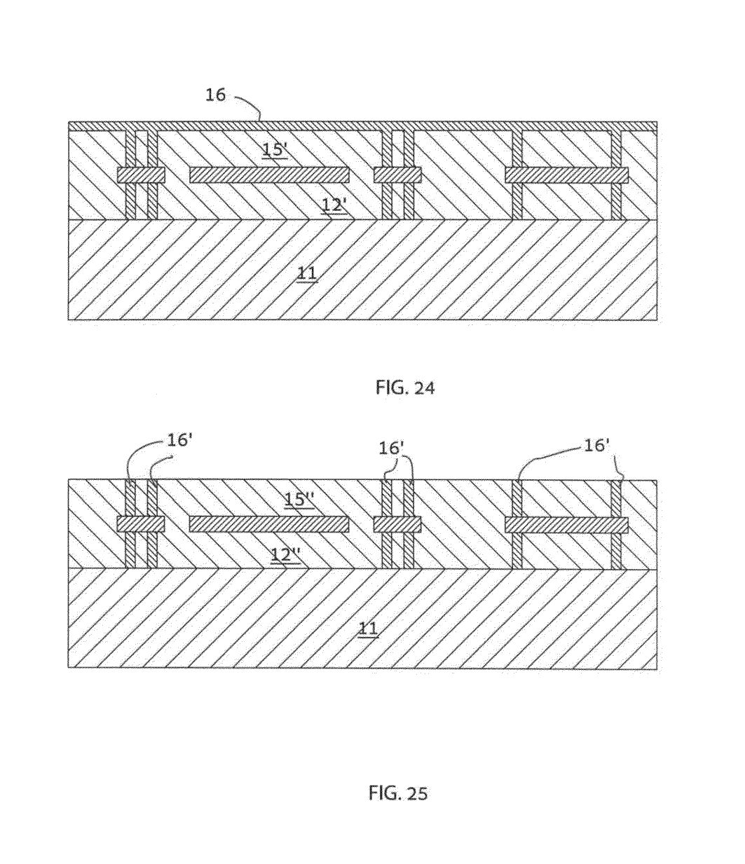

FIG. 25 illustrates the removal of the upper part of the passivation layer and the exposing of the electrically insulating etch stop elements 16′.

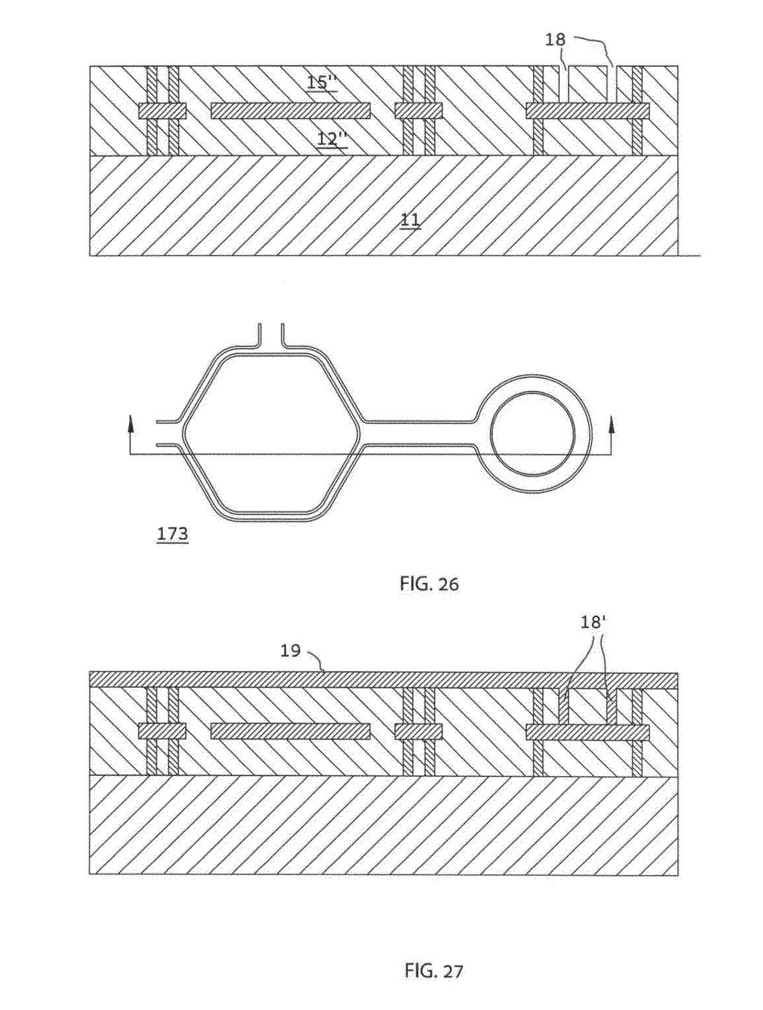

FIG. 26 illustrates further patterning of patterned sacrificial layer 15″ by forming additional holes 18. FIG. 26 also includes top view 173.

FIG. 27 illustrates the depositing of conductive layer 19. The conductive layer also fills holes 18 by conductive elements 18.

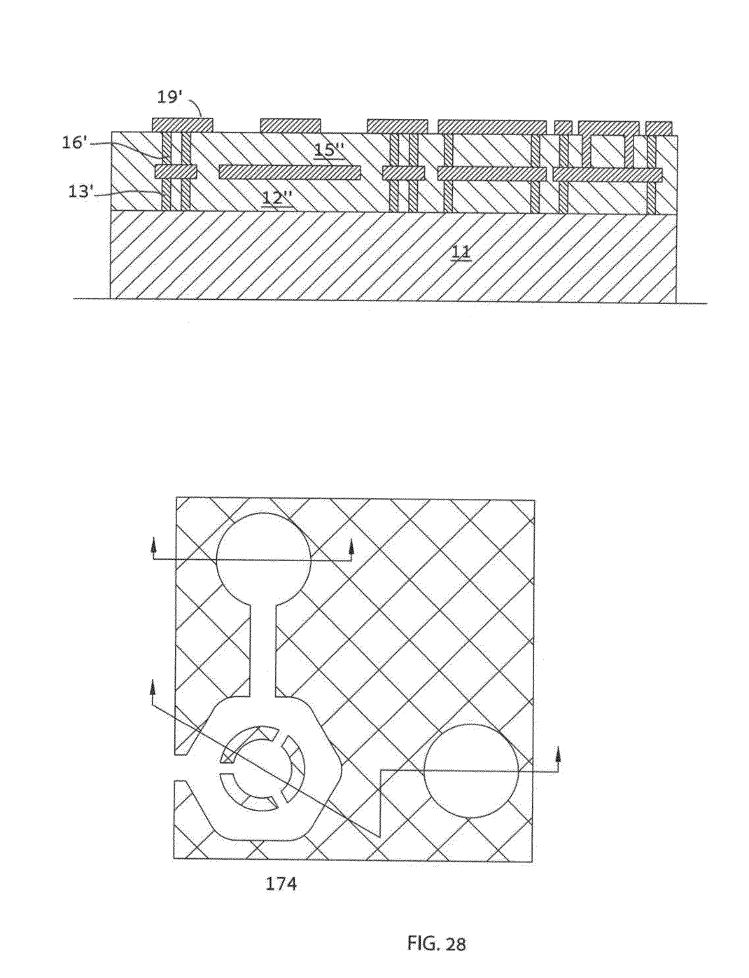

FIG. 28 illustrates the patterning of conductive layer 19 to form conductive layer patterns 19′ such as a blind. FIG. 28 also includes top view 174.

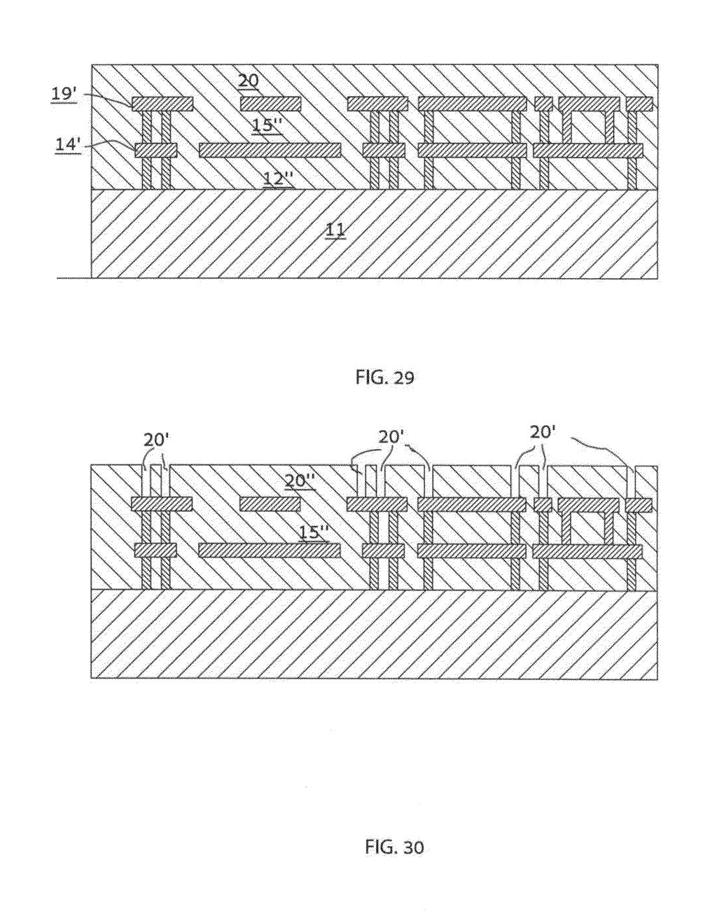

FIG. 29 illustrates the formation of top sacrificial layer 20 on conductive layer patterns 19′ and on parts of patterned sacrificial layer 15″ not covered by conductive layer patterns 19′.

FIG. 30 illustrates the patterning of top sacrificial layer 20—for example by forming holes 20′. The top patterned sacrificial layer is now denoted 20″.

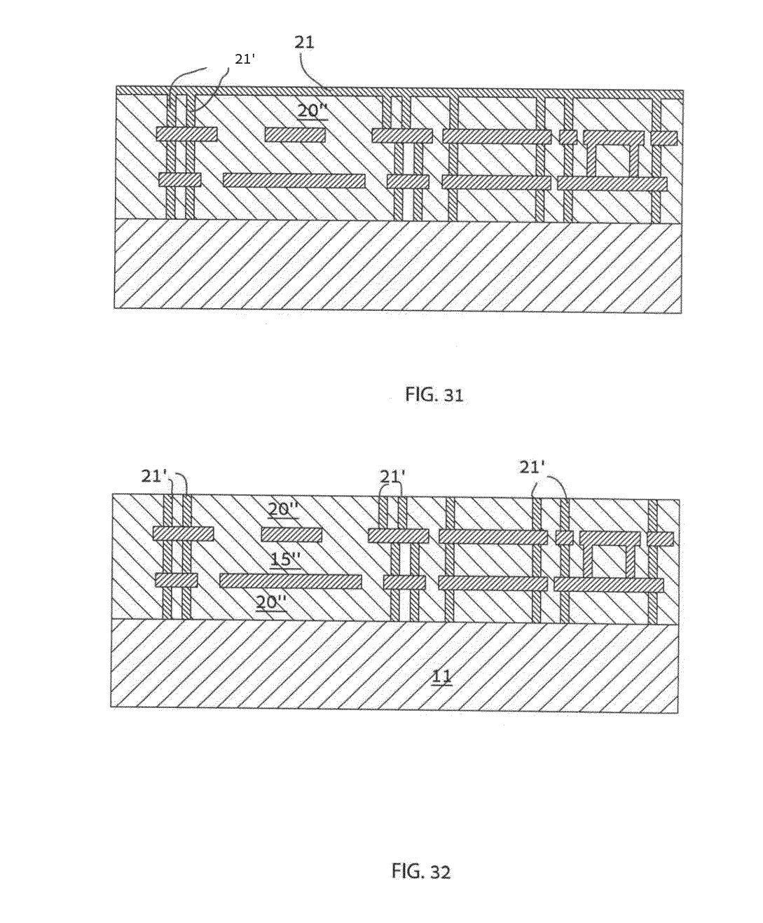

FIG. 31 illustrates the depositing of top passivation layer 21. The top passivation layer 21 includes an upper part that is positioned on the top of top patterned sacrificial layer 20″ and electrically insulating etch stop elements 21′ that fill holes 20′.

FIG. 32 illustrates the removal of the upper part of the passivation layer and the exposing of the electrically insulating etch stop elements 21′. The removal of the upper part of the passivation layer may be followed by drilling holes (not shown) that reach till conductive elements of the blind shutter layer.

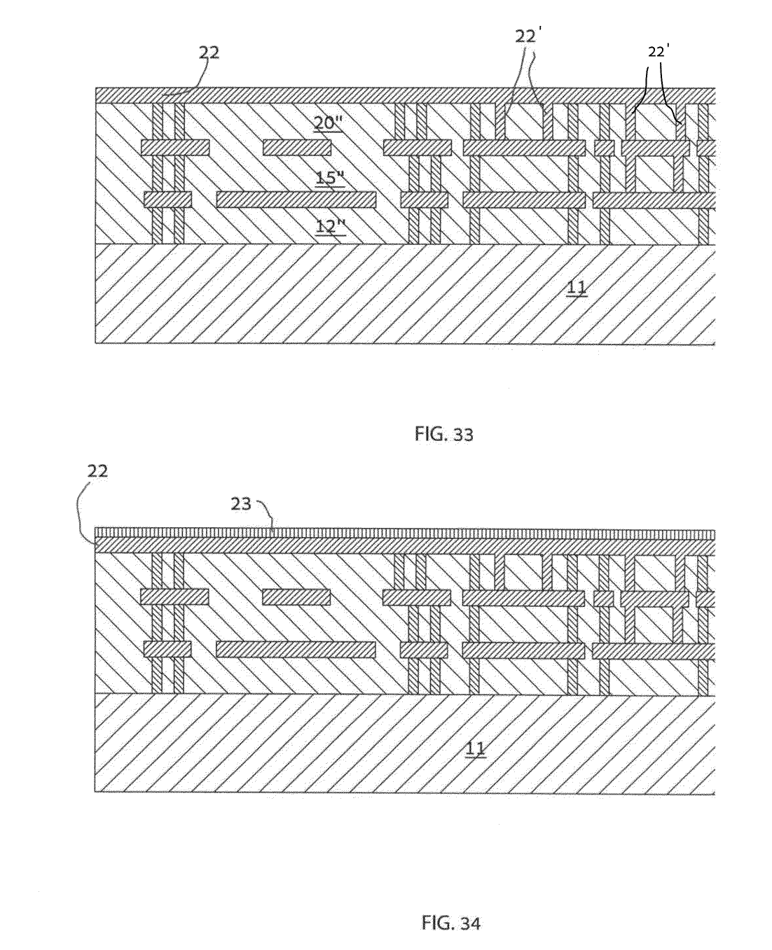

FIG. 33 illustrates the depositing of top conductive layer 22. The top conductive layer also fills (see conductive elements 22″) holes formed in patterned sacrificial layer (to form vertical conductive elements that are not used as etch stop elements) after the removal of the upper part of the top passivation layer.

FIG. 34 illustrates the deposition of metal layer 23.

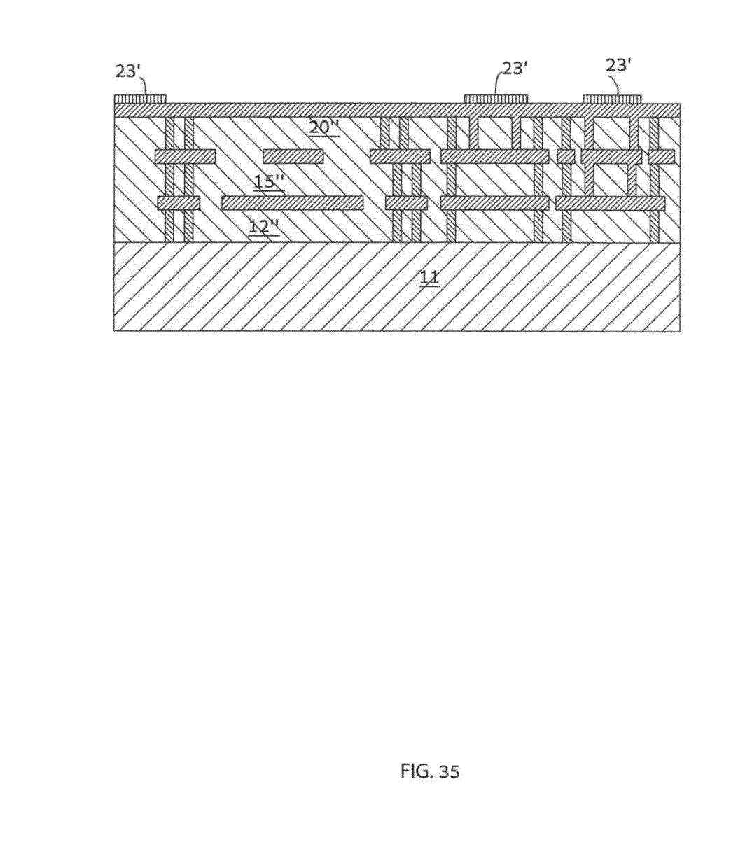

FIG. 35 illustrates the patterning of metal layer 23 to form metal layer patterns 23′.

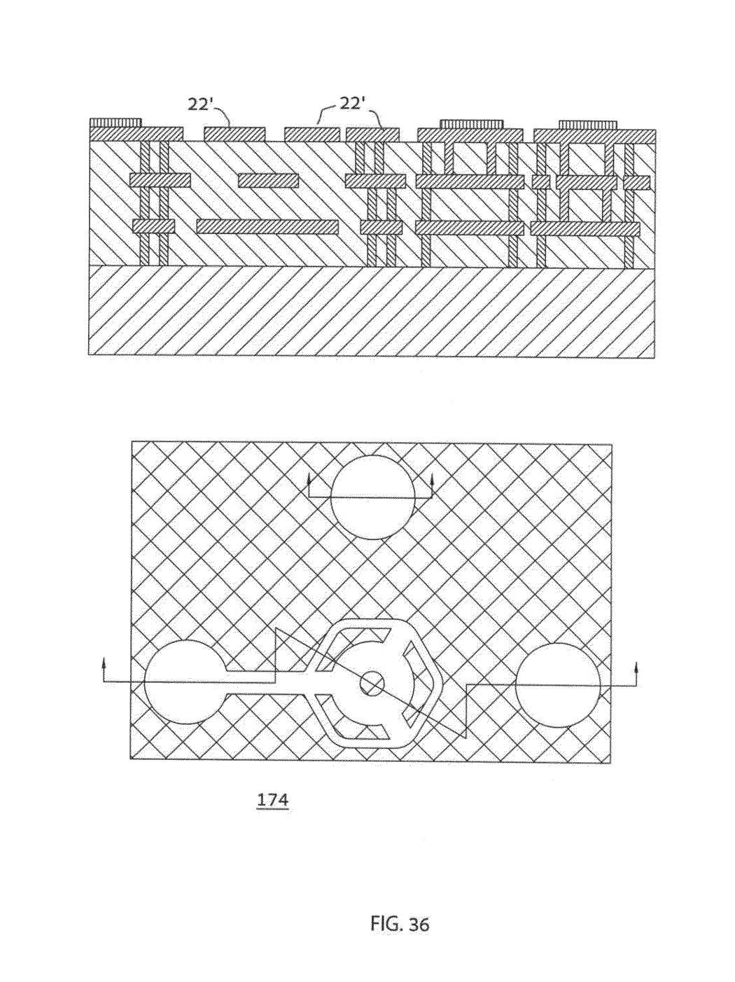

FIG. 36 illustrates the patterning of top conductive layer 22 to form top conductive layer patterns. FIG. 36 also includes top view 175.

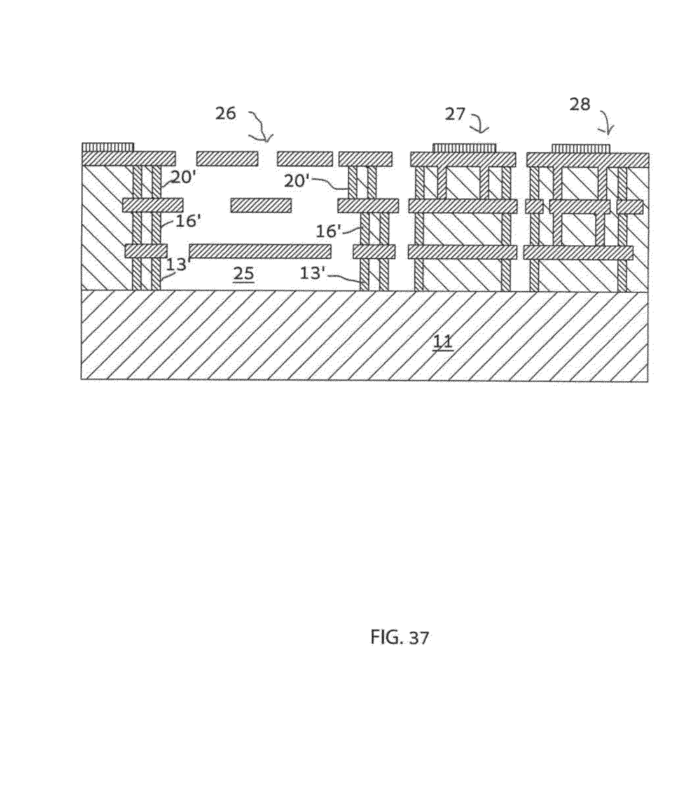

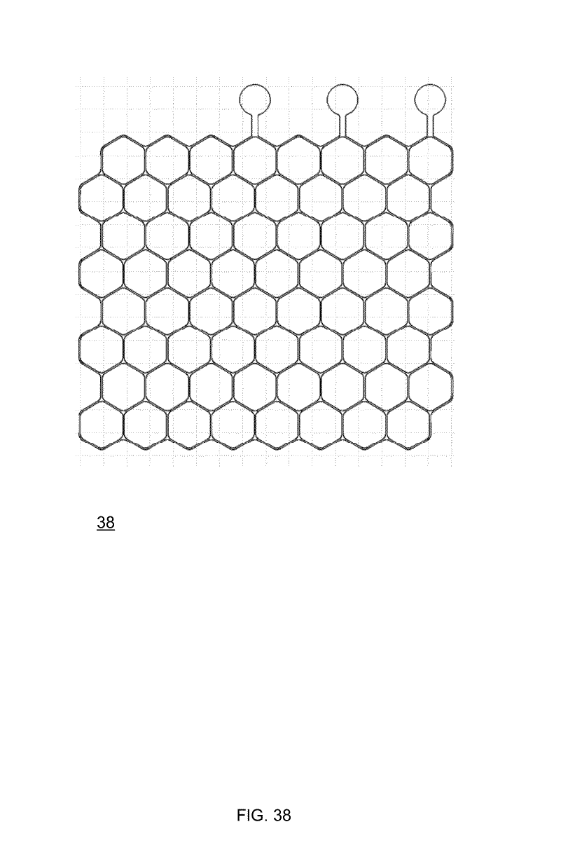

FIG. 37 illustrates the removal, by applying an etch process, each sacrificial layer pattern that is exposed to the etch process—and not stopped by insulating stop etch elements 210′, 16′, and 13′ thereby exposing support structures and functional elements that are formed by the multiple conductive layer patterns and by the top conductive pattern. The functional elements (such as MEMS cell 26) are included in a plurality of functional layers (membrane layer, blind layer and shutter layer), the plurality of functional layers are spaced apart from each other. A closed gap 25 is formed and is surrounded by a sidewall that includes lateral etch stop elements 13′, 26′ and 20′. FIG. 37 also illustrates support structures 27 and 28. The support structures are configured to provide structural support to the plurality of functional layers. Each functional layer is coupled to a conducting interface via a conductive path that is associated with the functional layer.

FIGS. 38-45 illustrate various masks 38-45 according to various embodiments of the invention. These masks are used to form a MEMS speaker that includes an array of MEMS cells that are substantially identical.

Mask 38 of FIG. 38 is a membrane layer release barrier mask.

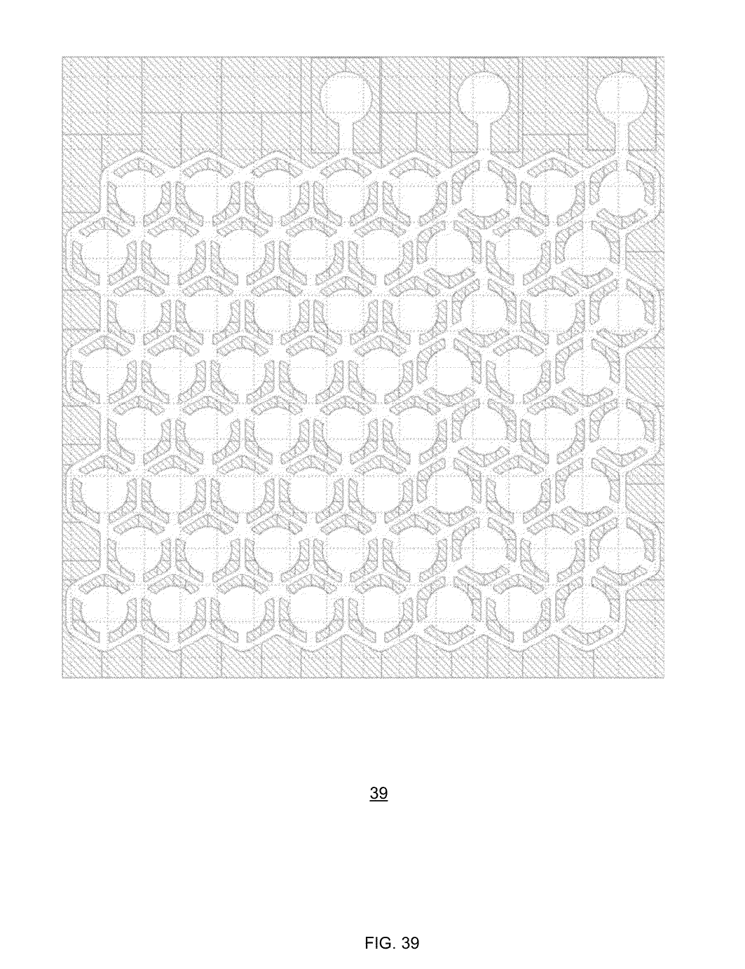

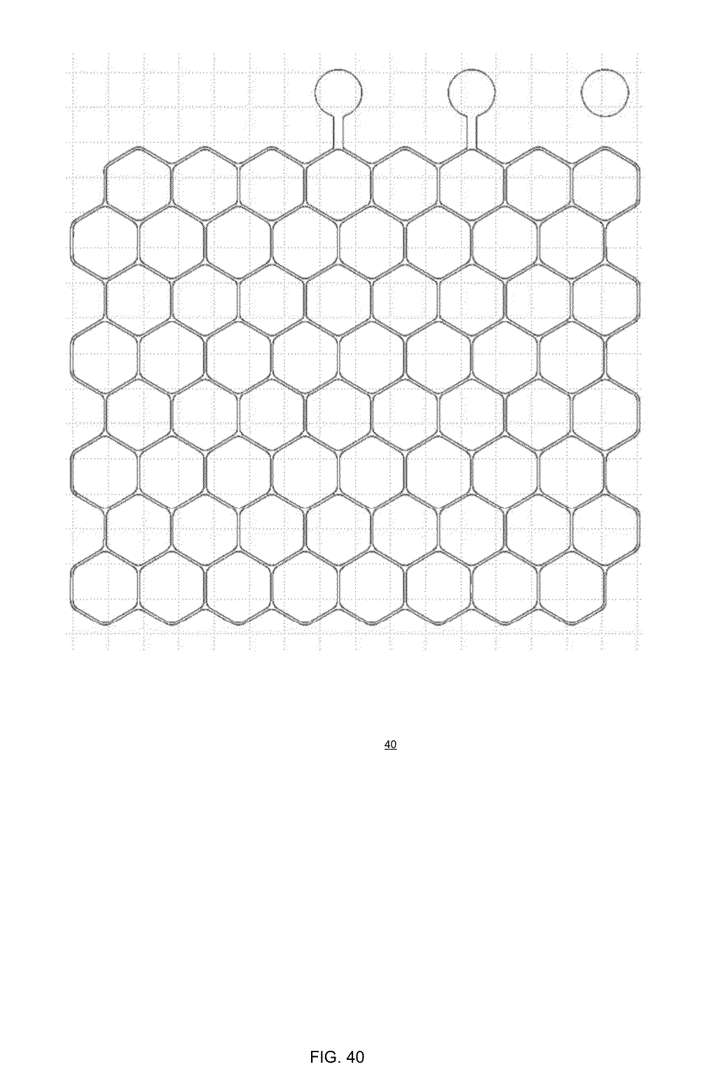

Mask 39 of FIG. 39 is a membrane layer mask.

Mask 40 of FIG. 40 is a perforated layer (blind layer) barrier mask.

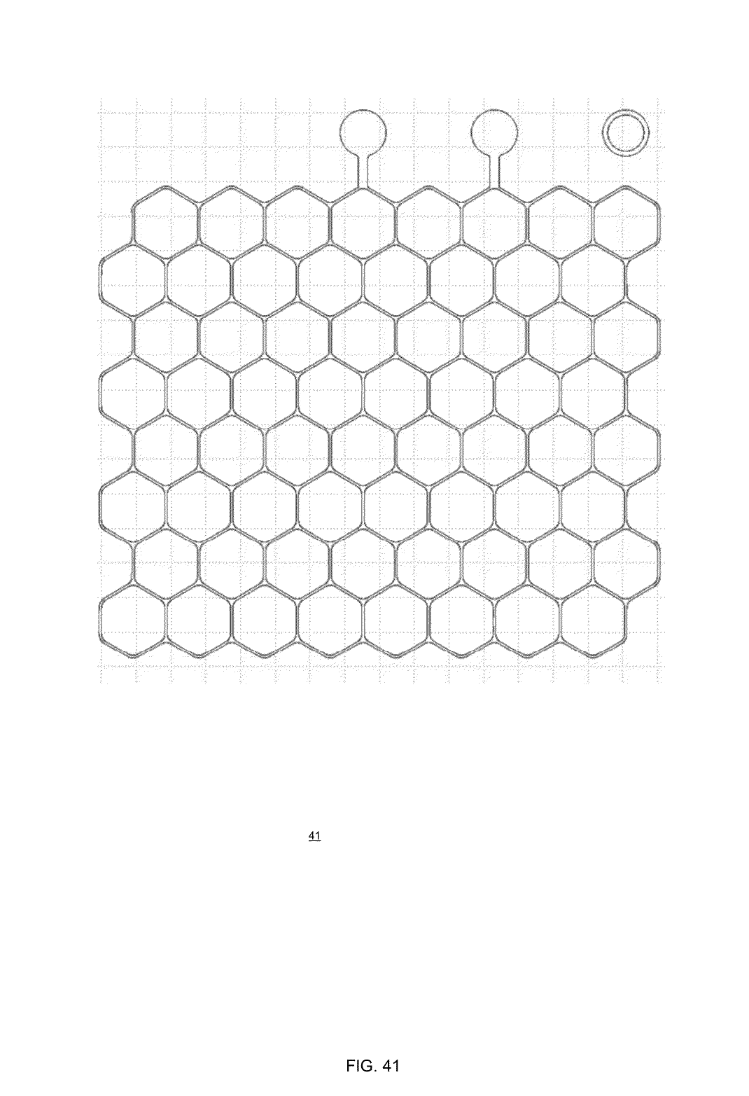

Mask 41 of FIG. 41 is a membrane layer via mask. The via mask is used to form the circle in the upper right corner—the rest of the figure is merely provided as a reference—to teach the location of the via.

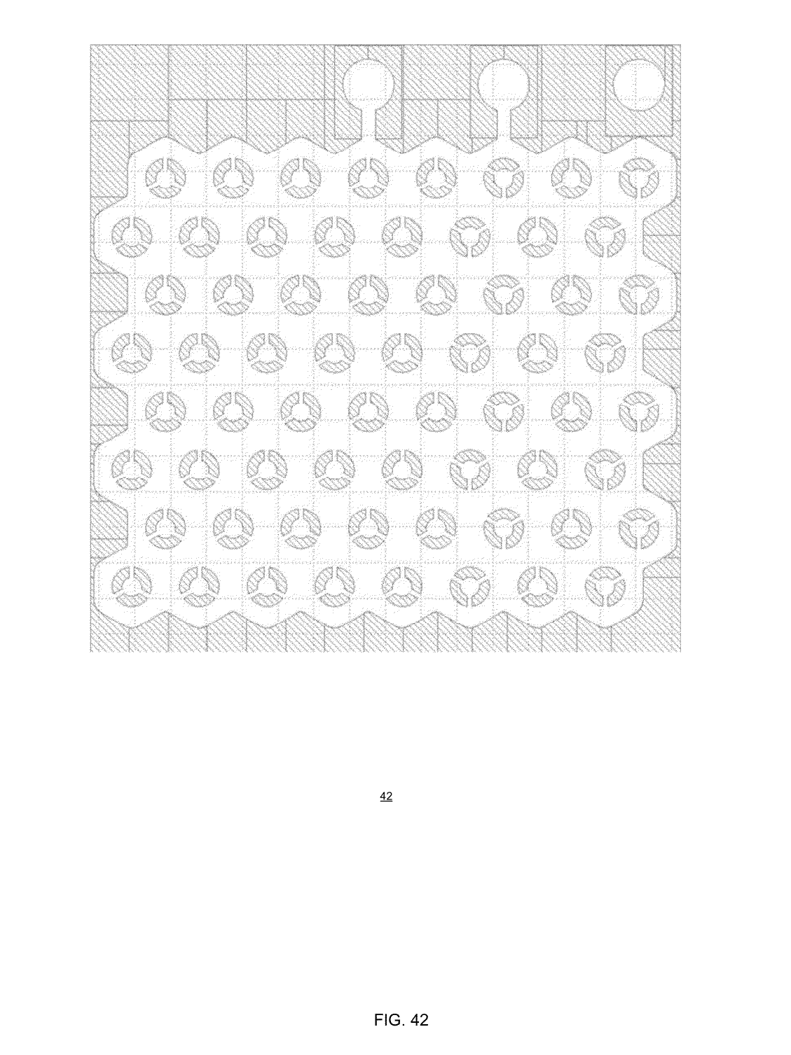

Mask 42 of FIG. 42 is a perforated layer (blind layer) mask.

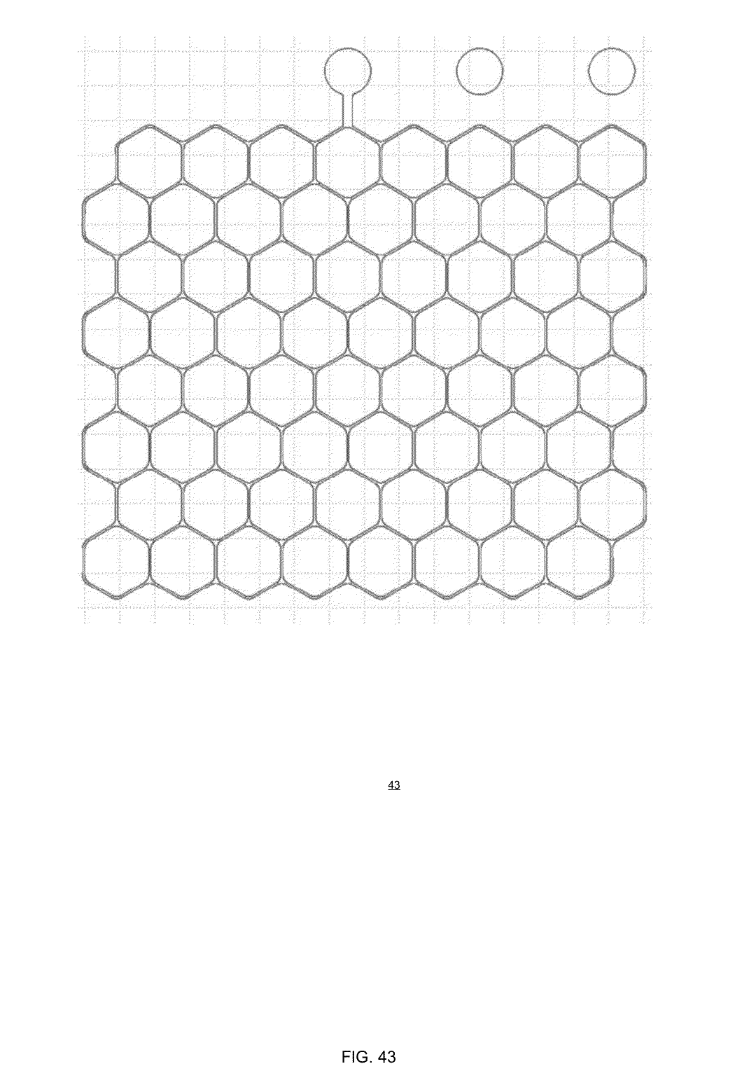

Mask 43 of FIG. 43 is a shutter release barrier mask.

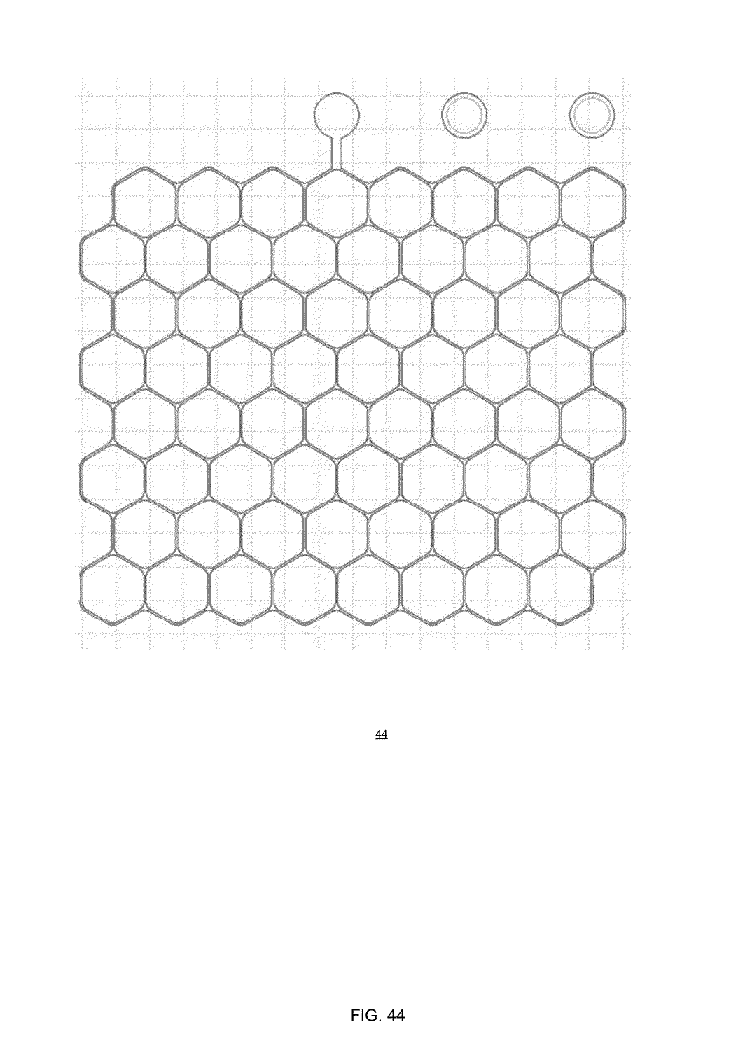

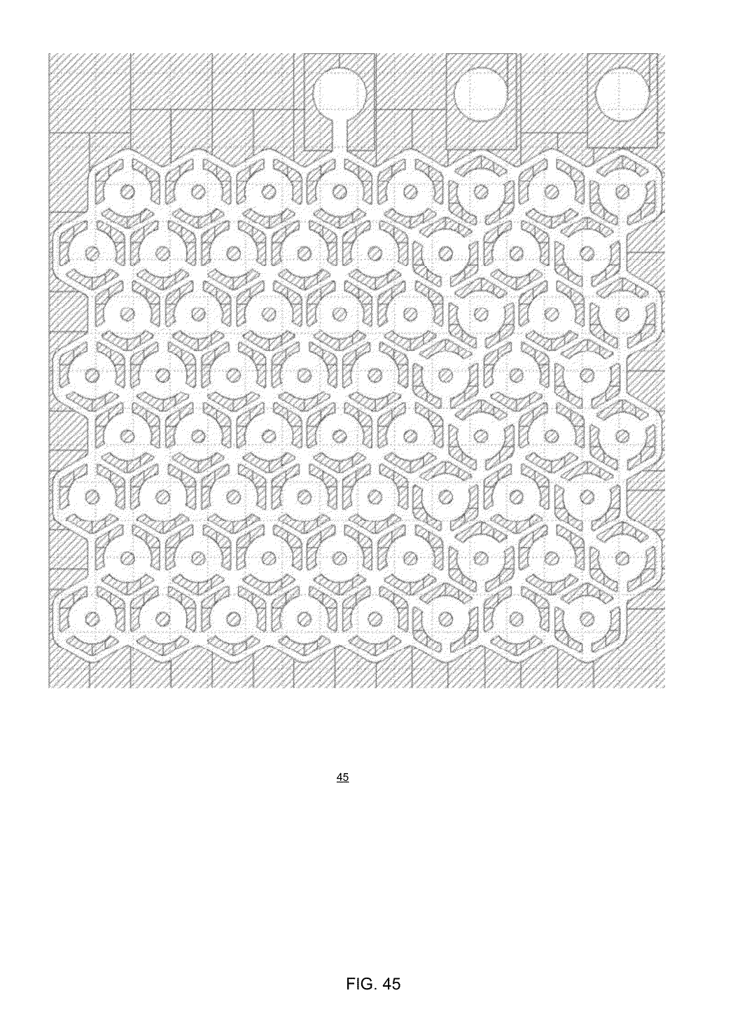

Mask 44 of FIG. 44 is the membrane and the perforated layer (blind layer) vias mask. The vis mask is used to form the two circles in the upper right corner of the figure. Are the via mask and all the rest is for reference—the rest of the figure is merely provided as reference—to teach the location of the via Mask 45 of FIG. 45 is a shutter pattern mask.

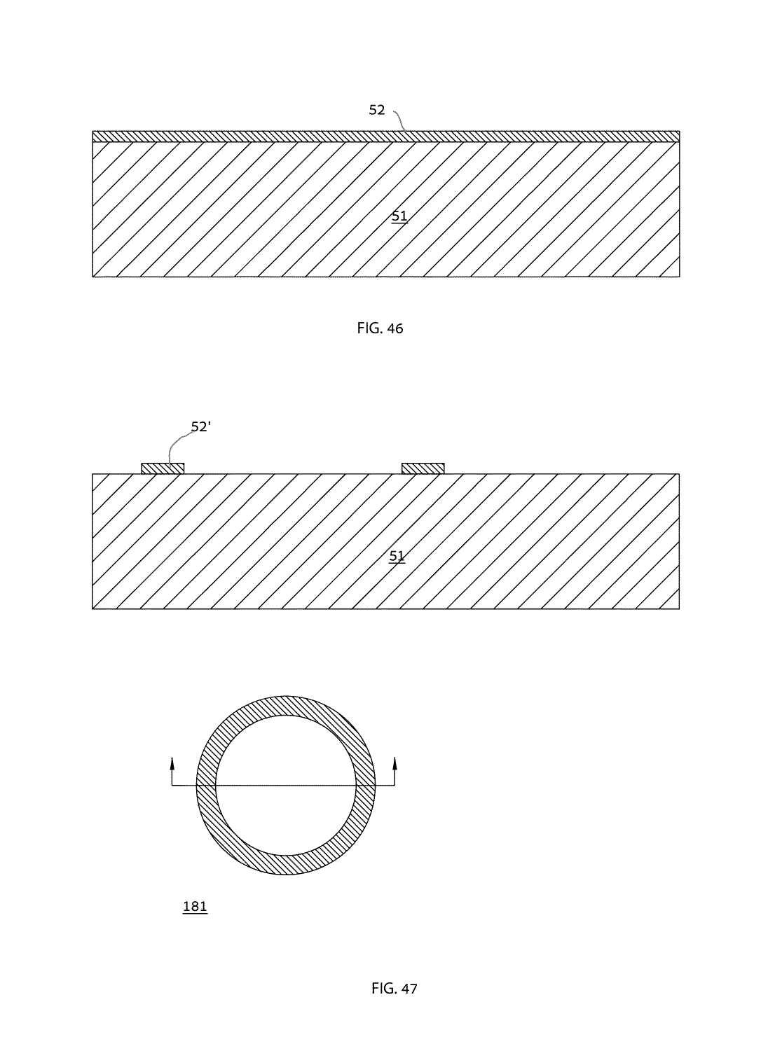

FIGS. 46-67 include top views and cross sectional views of a MEMS device during different manufacturing steps according to an embodiment of the invention. Note that in these figures the single cell of circular shape.

FIG. 46-67 illustrate a manufacturing process in which lateral etch stop elements positioned between the functional layers are electrically conductive.

The MEMS device of FIGS. 46-67 may be manufactured by executing method 1500.

FIG. 46 illustrates substrate 51 and passivation layer 52.

FIG. 47 illustrates the patterning of passivation layer 52 to form passivation layer patterns 52′. FIG. 47 also includes top view 181.

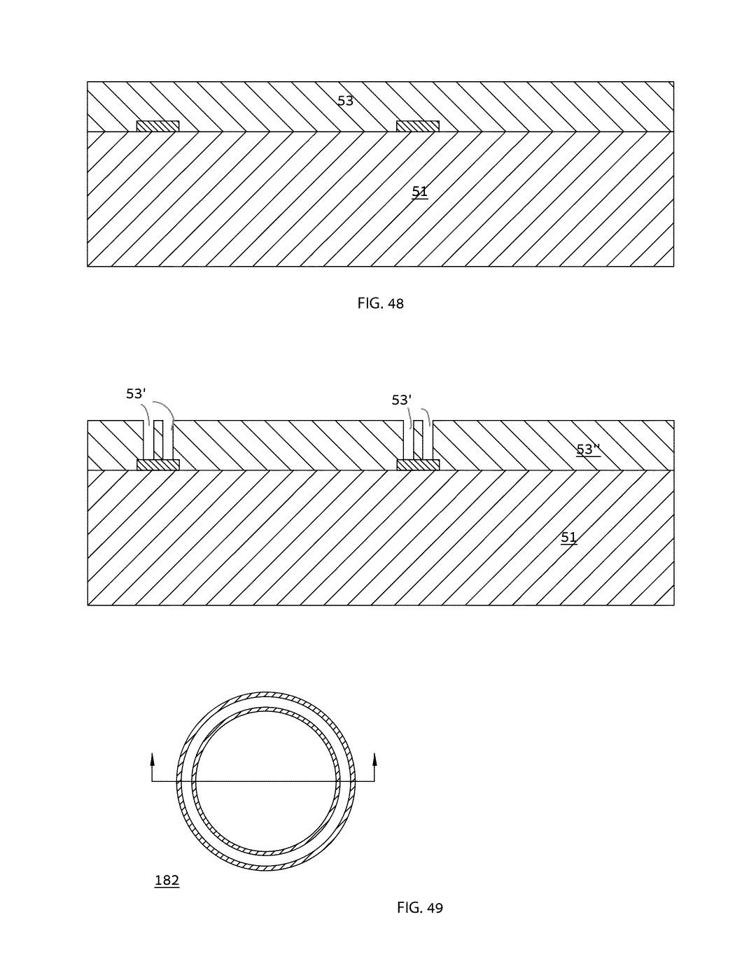

FIG. 48 illustrates the depositing of sacrificial layer 53.

FIG. 49 illustrates the patterning the sacrificial layer (now referred to as patterned sacrificial layer 53″) by forming holes 53′ above the passivation layer patterns 52′ thereby providing sacrificial layer pattern. FIG. 49 also includes top view 182.

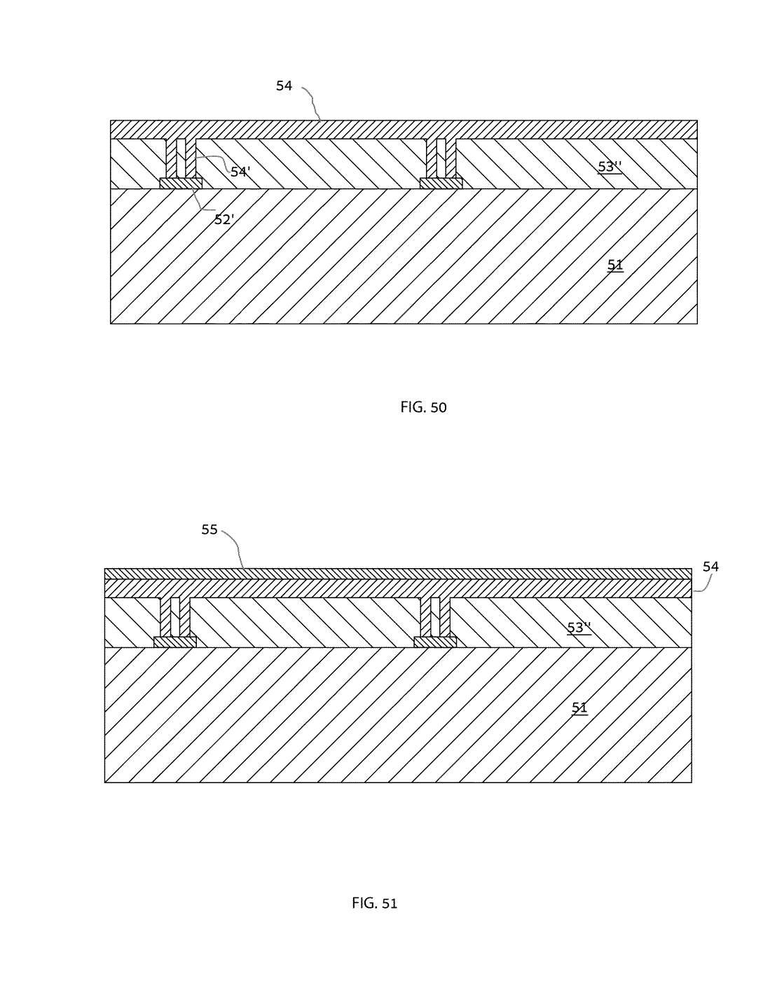

FIG. 50 illustrates the depositing of conductive layer 54. The conductive layer fills holes 53′ by lateral etch stop elements 54′ that are electrically conductive. The electrical etch stop elements 54′ are connected to the passivation layer patterns 52′.

FIG. 51 illustrates depositing of passivation layer 55.

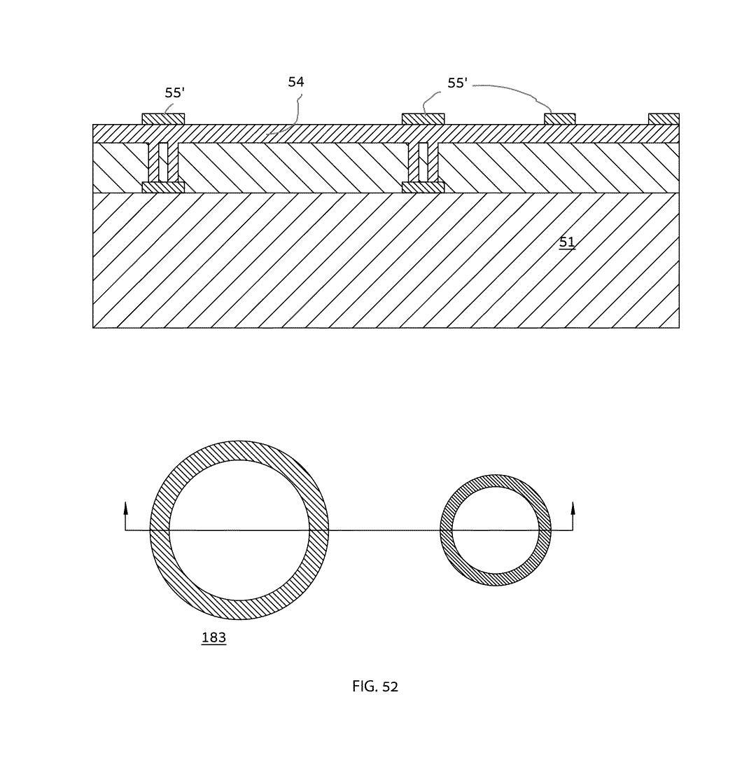

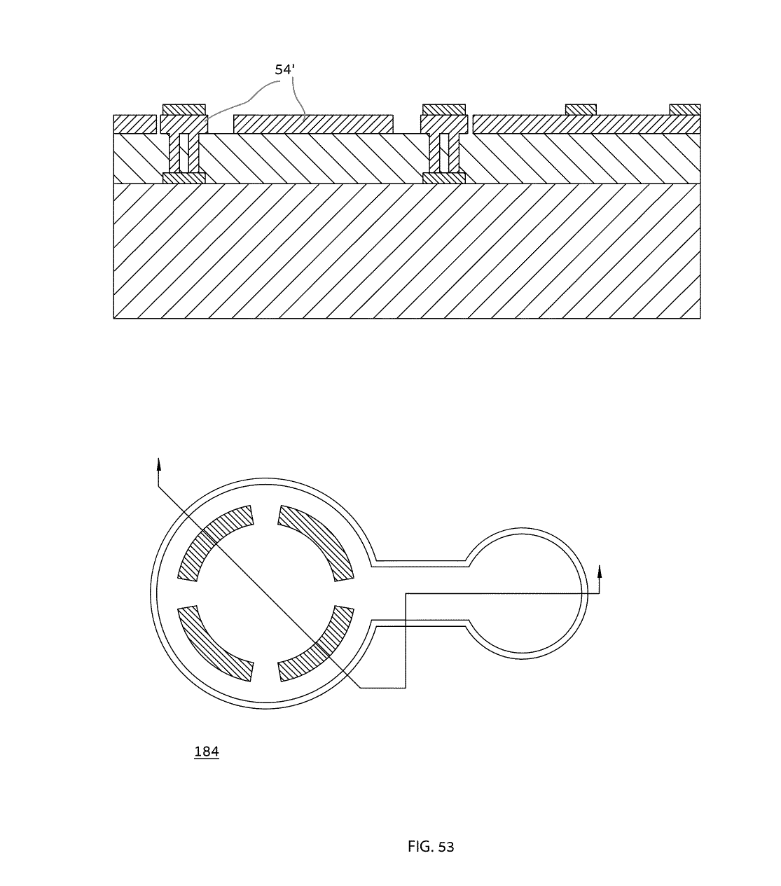

FIG. 52 illustrates the patterning of passivation layer 55 to form passivation layer patterns 55′. FIG. 52 also includes top view 183.

FIG. 53 illustrates the patterning of the conductive layer 54 to provide conductive layer pattern 54′. FIG. 53 also includes top view 184.

FIG. 54 illustrates the deposition of a sacrificial layer 53.

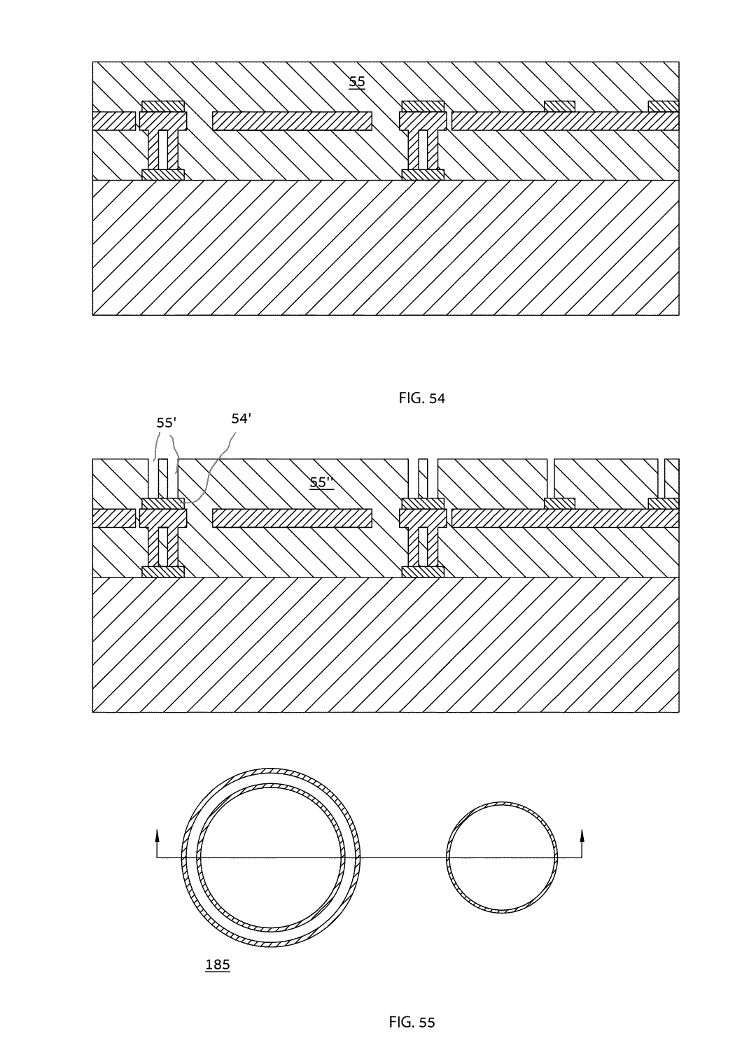

FIG. 55 illustrates the patterning the sacrificial layer (now referred to as patterned sacrificial layer 55″) by forming holes 55′ above the passivation layer patterns 54′ thereby providing sacrificial layer pattern. FIG. 55 also includes a top view 185.

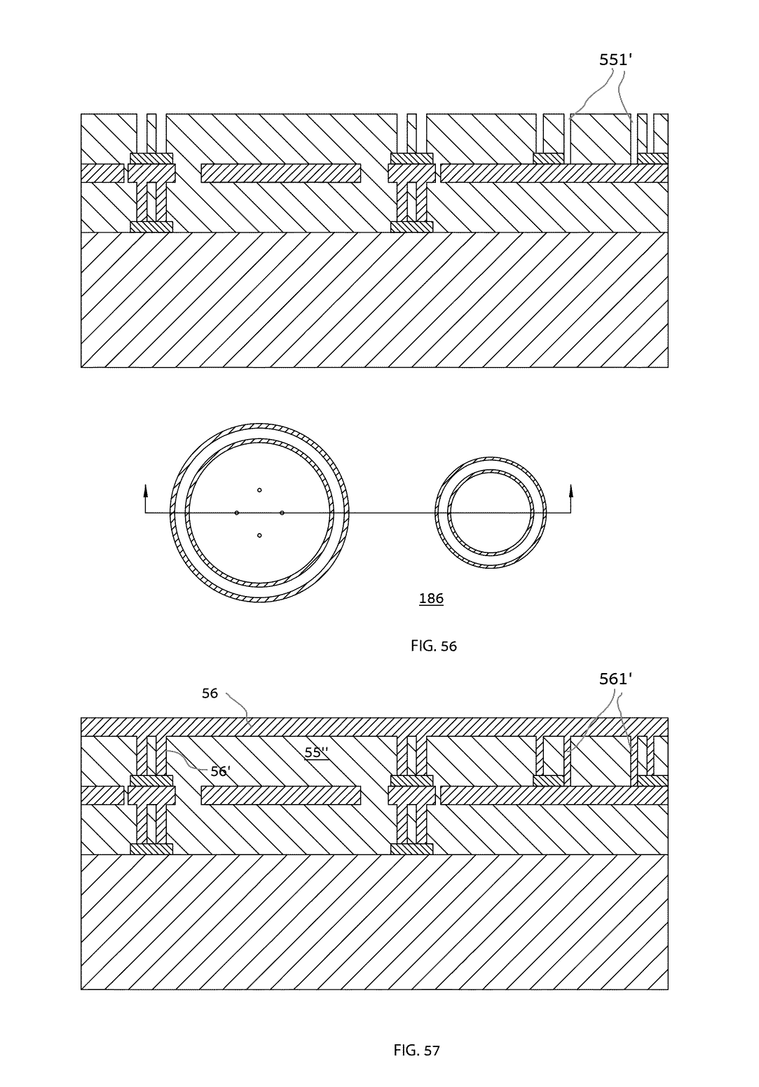

FIG. 56 illustrated forming additional holes 551 in the patterned sacrificial layer 55. FIG. 55 also includes a top view 186.

FIG. 57 illustrates depositing conductive layer 56 thereby filling holes 55′ to form etch stop elements 56′ that are electrically conductive and also to form electrical elements 561 that electrically couple conductive layer 56 to a part of the conductive layer pattern 54′.

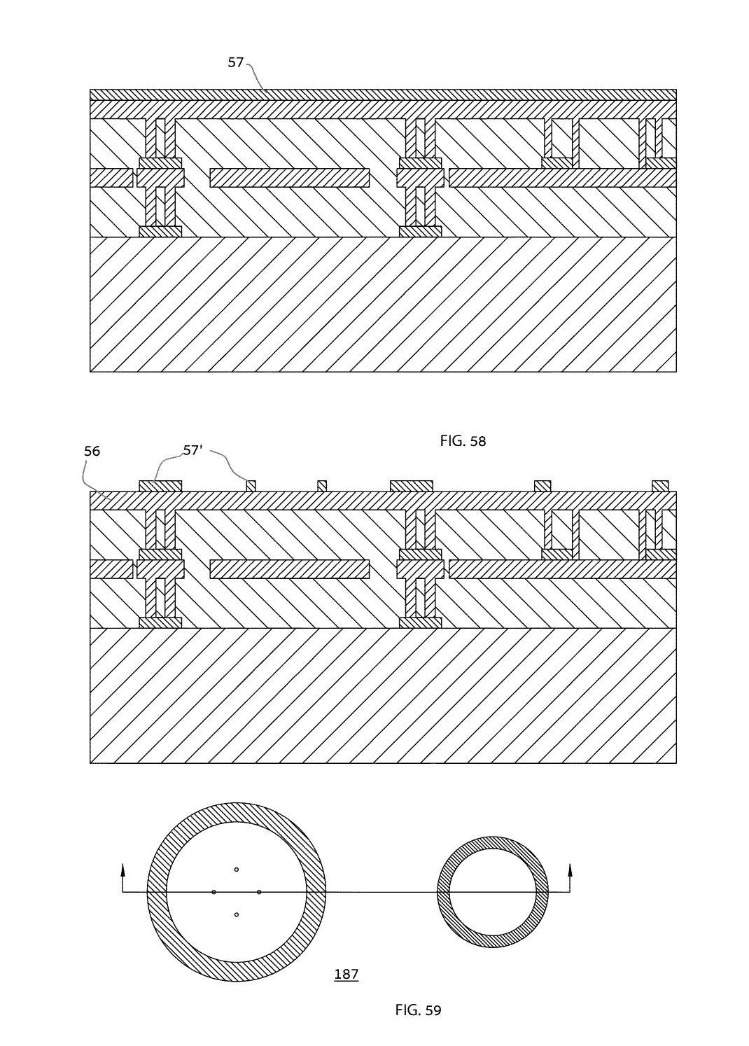

FIG. 58 illustrates depositing of passivation layer 57.

FIG. 59 illustrates the patterning of passivation layer 57 to form passivation layer patterns 57′. FIG. 59 also includes top view 187.

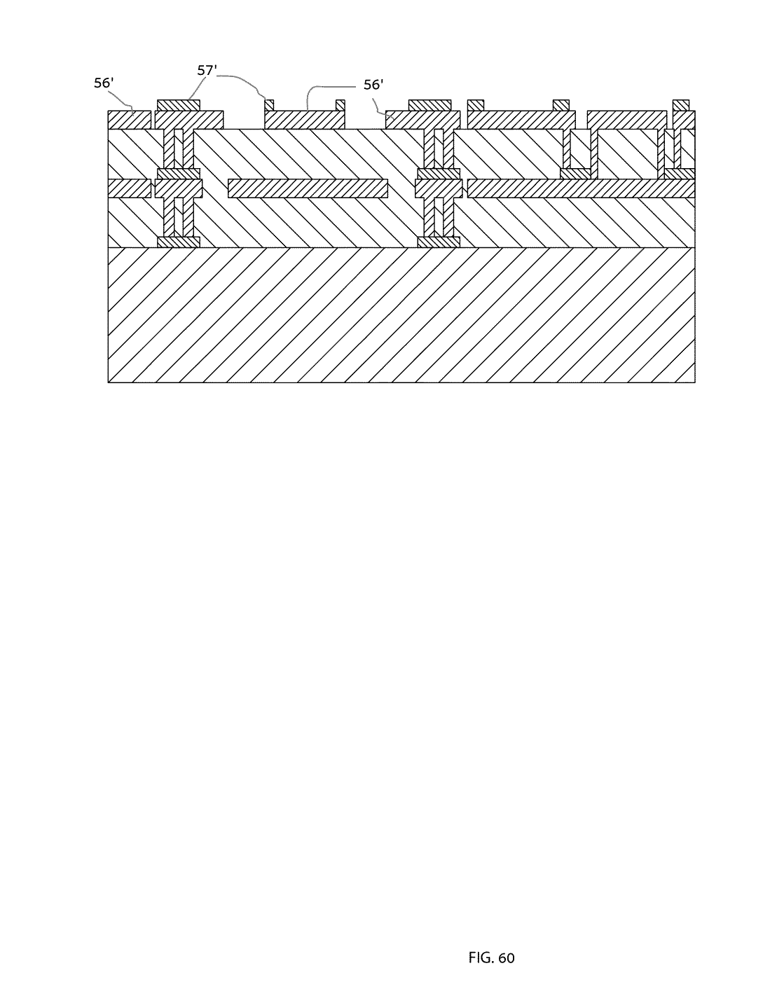

FIG. 60 illustrates the patterning of the conductive layer 56 to provide conductive layer pattern 56′.

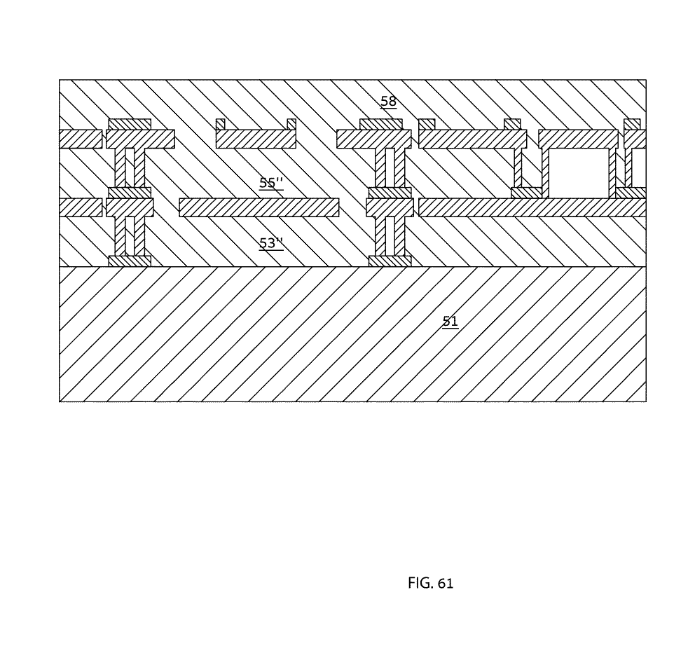

FIG. 61 illustrates the deposition of a top sacrificial layer 58.

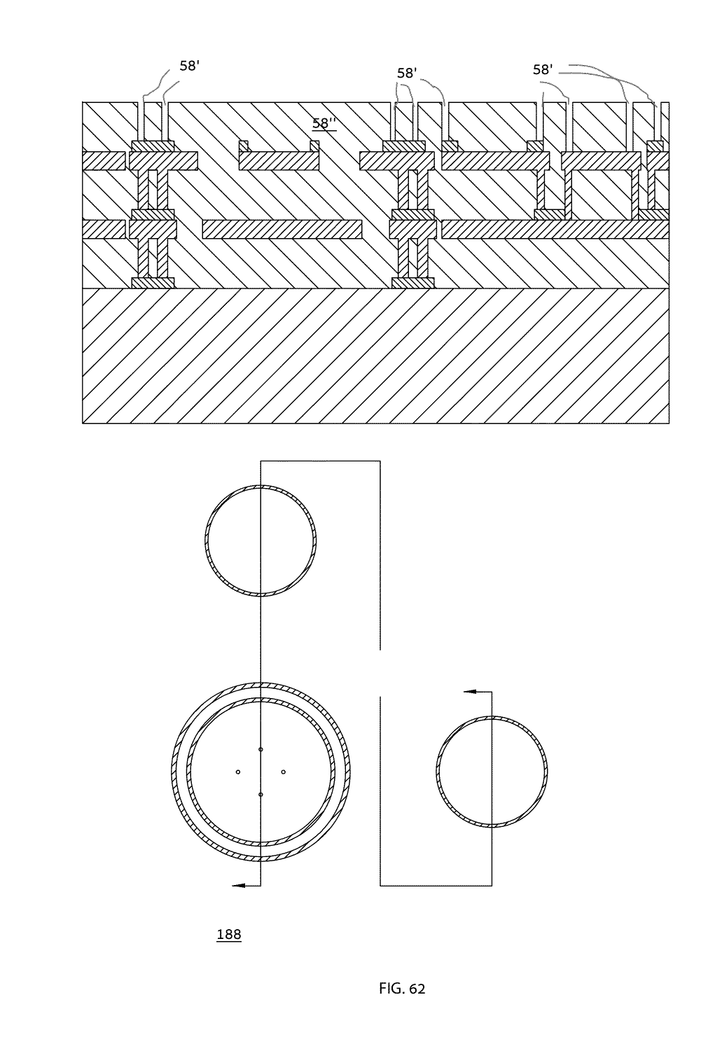

FIG. 62 illustrates the patterning the top sacrificial layer (now referred to as patterned top sacrificial layer 58″) by forming holes 58′ above the passivation layer patterns 57′ thereby providing sacrificial layer pattern. FIG. 62 also includes a top view 188.

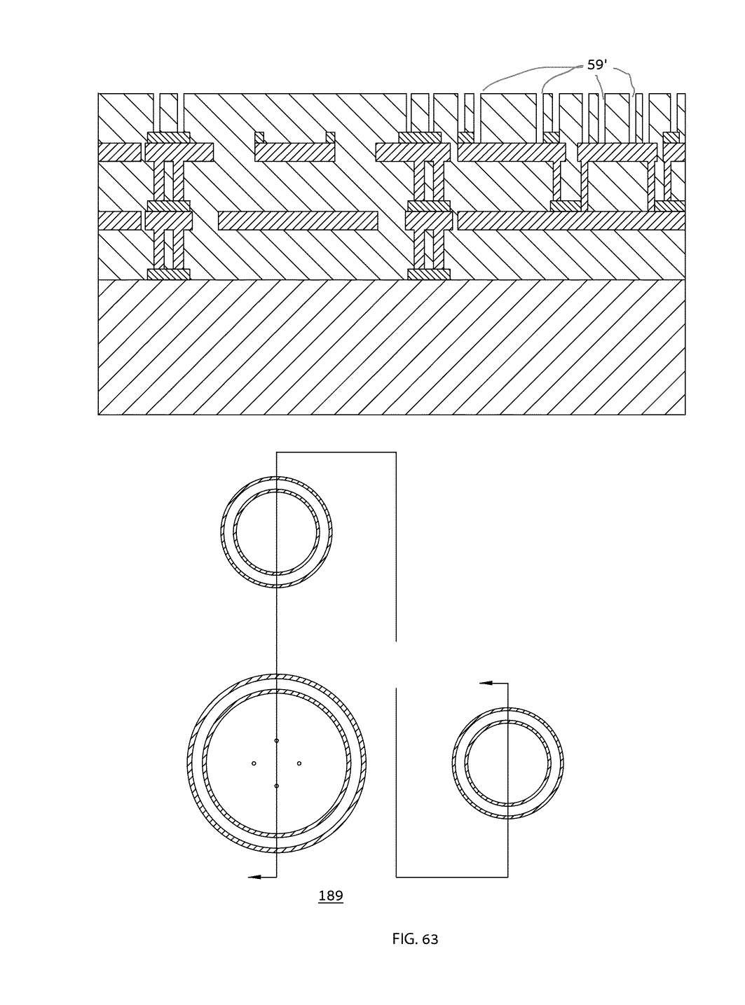

FIG. 63 illustrated forming additional holes 59′ in the patterned top sacrificial layer 58″. FIG. 63 also includes a top view 189.

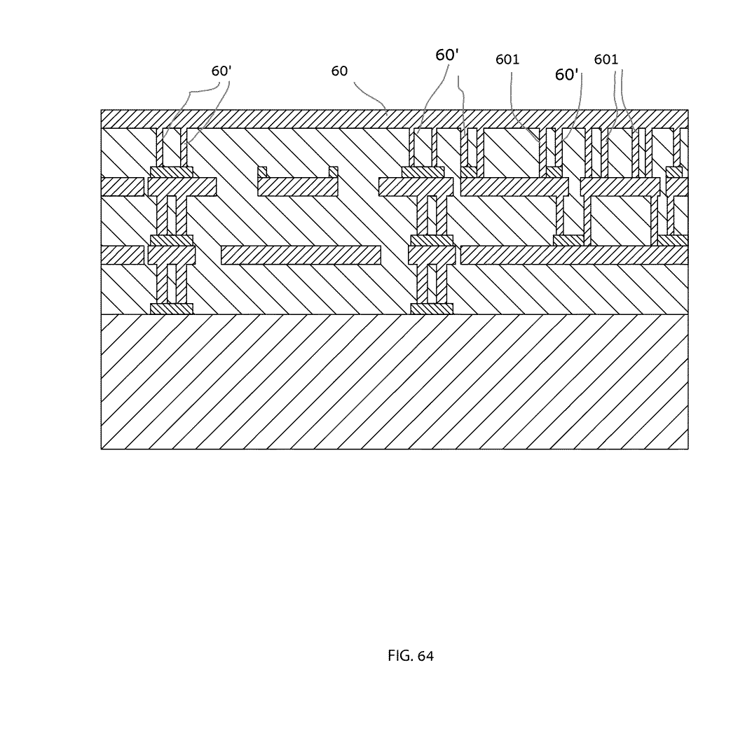

FIG. 64 illustrates depositing top conductive layer 60 thereby filling holes 59′ to form etch stop elements 60′ that are electrically conductive and also to form electrical elements 601 that electrically couple top conductive layer 60 to a part of conductive layer pattern 56′.

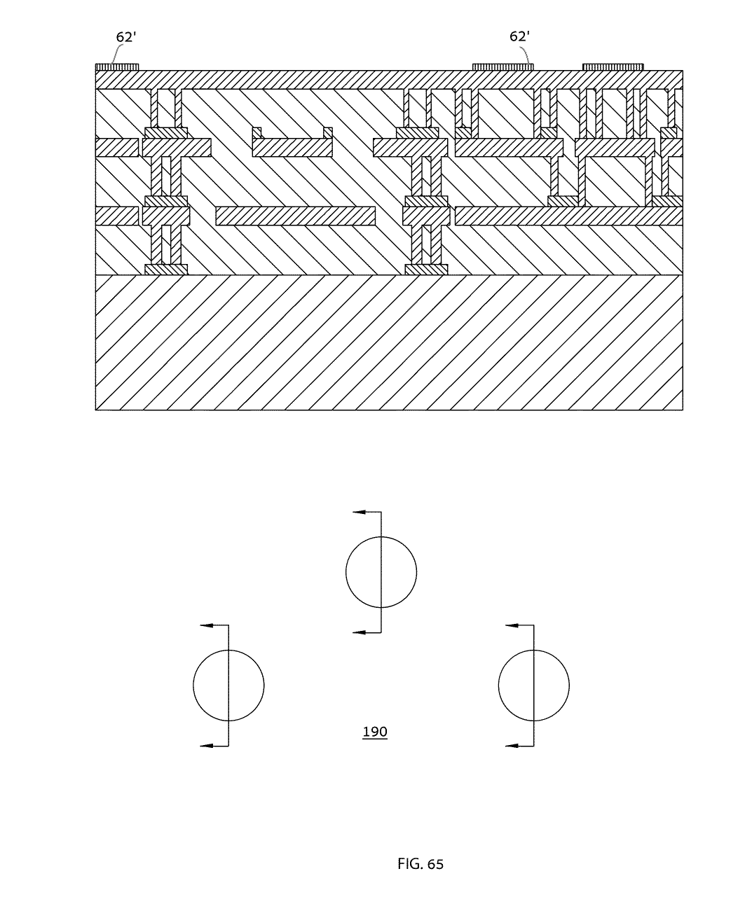

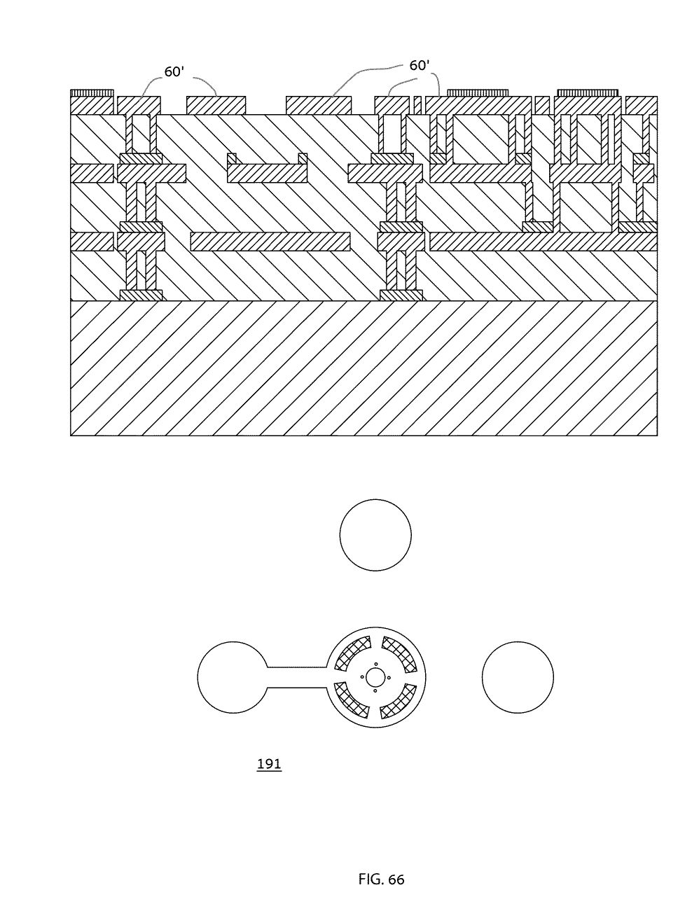

FIG. 65 illustrates depositing of metal layer and patterning the metal layer to form metal layer pattern 62′. FIG. 65 also includes a top view 190.

FIG. 66 illustrates the patterning of the top conductive layer 60 to provide conductive layer pattern 60′. FIG. 60 also includes top view 191 that illustrates a shutter and a support structure.

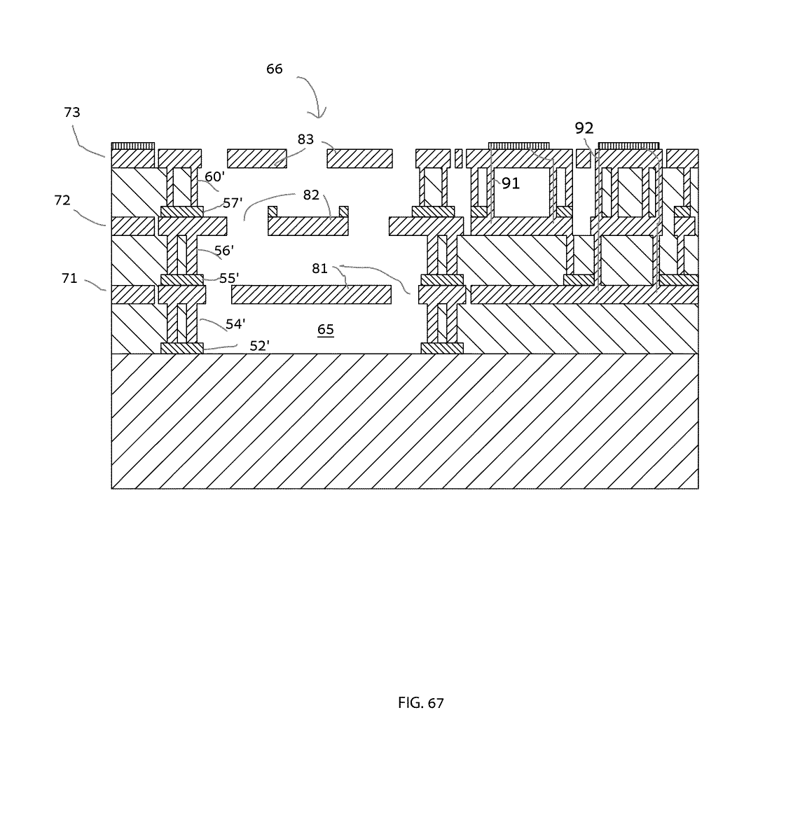

FIG. 67 illustrates the removing, by applying an etch process, each sacrificial layer pattern that is exposed to the etch process thereby exposing support structures and functional elements that are formed by the multiple conductive layer patterns. The functional elements are included in a plurality of functional layers—membrane layer 71, blind layer 72 and shutter layer 73. The plurality of functional layers are spaced apart from each other. The support structures are configured to provide structural support to the plurality of functional layers. Each functional layer is coupled to a conducting interface via a conductive path (such as 91 and 92) that is associated with the functional layer. The support structures comprise lateral etch stop elements. The lateral etch stop elements may be electrically conductive.

Any reference to any of the terms “comprise”, “comprises”, “comprising” “including”, “may include” and “includes” may be applied to any of the terms “consists”, “consisting”, “and consisting essentially of”. For example—any of figures describing masks used for implementing the MEMS device may include more components that those illustrated in the figure, only the components illustrated in the figure or substantially only the components illustrate in the figure.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between MEMS elements are merely illustrative and that alternative embodiments may merge MEMS elements or impose an alternate decomposition of functionality upon various MEMS elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single MEMS device. Alternatively, the examples may be implemented as any number of separate MEMS devices or separate MEMS devices interconnected with each other in a suitable manner. However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A micro-electromechanical system (MEMS) device that comprises a substrate, support structures, functional elements and conductive paths that comprise conductive elements;
wherein the functional elements are included in a plurality of functional layers, the plurality of functional layers are spaced apart from each other;
wherein the support structures are configured to provide structural support to the plurality of functional layers;
wherein each functional layer is coupled to a conducting interface via a conductive path that is associated with the functional layer;
wherein the support structures comprise lateral etch stop elements.

2. The MEMS device according to claim 1, wherein the etch stop elements are electrically insulating.

3. The MEMS device according to claim 1, wherein each support structure comprises lateral etch stop elements that are electrically conductive.

4. The MEMS device according to claim 3, wherein the lateral etch stop elements of the support structures are positioned between the plurality of functional layers without electrically coupling the plurality of functional layers.

5. The MEMS device according to claim 3, wherein each lateral etch stop element is electrically insulated from a functional layer positioned below the lateral etch stop by a passivation layer element.

6. The MEMS device according to claim 1, wherein each support structure comprises a sidewall that comprises one or more lateral etch stop elements that are electrically insulating.

7. The MEMS device according to claim 6, wherein the sidewall of each support structure further comprises one or more conductive elements that belong to a functional layer.

8. The MEMS device according to claim 1 wherein a given support structure comprises first portions that are included within the plurality of functional layers and second portions which are positioned between the plurality of functional layers.

9. The MEMS device according to claim 1, wherein each conductive path is formed, at least in part, within a support structure.

10. The MEMS device according to claim 9, wherein conductive paths associated with different functional layers are formed within different support structures.

11. The MEMS device according to claim 1, wherein each conductive path comprises horizontal conductive elements that belong to the functions layers and vertical conductive elements positioned between the functional layers.

12. The MEMS device according to claim 1 wherein the support structures comprise core segments that are delimited by the lateral etch stop elements.

13. The MEMS device according to claim 12, wherein the one or more core segments are made of a material selected out of Tetraethyl orthosilicate, Silicon Oxide, and undoped Silica glass (USG).

14. The MEMS device according to claim 1 wherein a number of functional layers of the plurality of functional layers exceeds three.

15. The MEMS device according to claim 1 wherein the MEMS circuits comprise a membrane, a blind and a shutter.

16. The MEMS device according to claim 15 wherein the membrane, the blind and the shutter belong to different functional layers of the plurality of functional layers.

17. The MEMS device according to claim 15 wherein the membrane, blind and the shutter are positioned within a space that has closed sides.

18. The MEMS device according to claim 1 wherein a first functional element belongs to a first functional layer and wherein a second functional element belongs to a second functional layer.

19. The MEMS device according to claim 1, wherein a certain functional layer comprises multiple functional elements.

20. The MEMS device according to claim 19, wherein all of the multiple functional elements of the certain functional layer are substantially identical to each other.

21. The MEMS device according to claim 19, wherein at least some functional elements of the multiple functional elements of the certain functional layer differ from each other.

22. The MEMS device according to claim 19, wherein all of the multiple functional elements of the certain functional layer are electrically coupled to each other.

23. The MEMS device according to claim 19, wherein some of the multiple functional elements of the certain functional layer are not electrically coupled to each other.

24. The MEMS device according to claim 1, wherein each functional layer of at least two functional layers comprises multiple functional elements.

25. A method for manufacturing a micro-electromechanical system (MEMS) device, the method comprises:
generating multiple sacrificial layer patterns and multiple conductive layer patterns by repeating the steps of depositing a sacrificial layer; patterning the sacrificial layer to provide a sacrificial layer pattern; depositing a passivation layer; removing an upper part of the passivation layer to expose the sacrificial layer pattern; depositing a conductive layer; and patterning the conductive layer, thereby forming a conductive layer pattern;
depositing a top sacrificial layer; patterning the top sacrificial layer to provide a top sacrificial layer pattern;
depositing a top passivation layer;
removing the upper part of the top passivation layer to expose the sacrificial layer pattern;
depositing a top conductive layer;
depositing a metal layer;
patterning the metal layer to provide a metal layer pattern;
patterning the top conductive layer thereby forming a conductive layer pattern; and
removing, by applying an etch process, each sacrificial layer pattern that is exposed to the etch process thereby exposing support structures and functional elements that are formed by the multiple conductive layer patterns and the top conductive layer pattern; wherein the functional elements are included in a plurality of functional layers, the plurality of functional layers are spaced apart from each other; wherein the support structures are configured to provide structural support to the plurality of functional layers; and wherein the support structures comprise electrically insulating lateral etch stop elements.

26. The method according to claim 25, wherein the multiple conductive layer patterns define edges of the insulating support structures.

27. The method according to claim 25, wherein the multiple conductive layer patterns define the functional elements.

28. A method for manufacturing a micro-electromechanical system (MEMS) device, the method comprises:
depositing a passivation layer on a substrate and patterning the passivation layer to provide a passivation layer pattern;
generating multiple sacrificial layer patterns and multiple conductive layer patterns by repeating the steps of: depositing a sacrificial layer; patterning the sacrificial layer to provide a sacrificial layer pattern; depositing a conductive layer; depositing a passivation layer; patterning the passivation layer to provide a passivation layer pattern; and patterning the conductive layer thereby forming a conductive layer pattern;
depositing a top sacrificial layer;
patterning the top sacrificial layer to provide a sacrificial layer pattern; depositing a top conductive layer;
depositing a metal layer; patterning the metal layer to provide a metal layer pattern; and
patterning the top conductive layer thereby forming a top conductive layer pattern and removing, by applying an etch process, each sacrificial layer pattern that is exposed to the etch process thereby exposing support structures and functional elements that are formed by the multiple conductive layer patterns and the top conductive layer pattern; wherein the functional elements are included in a plurality of functional layers, the plurality of functional layers are spaced apart from each other; wherein the support structures are configured to provide structural support to the plurality of functional layers; and wherein the support structures comprise electrically conductive lateral etch stop elements.
